(19) United States
(12) Patent Application Publication
(10) Pub. No.: US 2016/0186309 A1
(43) Pub. Date: Jun. 30, 2016

(54) Gas Barrier Coating Techniques and Articles Produced Thereof

(71) Applicant: Avery Dennison Corporation, Glendale, CA (US)

(72) Inventor: Kevin O. HENDERSON, Willoughby Hills, OH (US)

(21) Appl. No.: 14/967,749

(22) Filed: Dec. 14, 2015

Related U.S. Application Data
(60) Provisional application No. 62/097,971, filed on Dec. 30, 2014.

(51) Int. Cl. C23C 14/24; B05D 1/00; B05D 1/30; B05D 1/18; B05D 1/02; B05D 1/28

(52) U.S. Cl. CPC C23C 14/24; B05D 1/02; B05D 1/28; B05D 1/305; B05D 1/18; B05D 1/005; B05D 1/007

(57) ABSTRACT

Methods of forming a barrier layer on a substrate to form a halogen-free multi-layer construction configured to increase the barrier properties of the substrate are described. The barrier layer can reduce the oxygen transmission rate through the construction and can reduce the amount of air on one side of the construction. The methods include dissolving a highly amorphous vinyl alcohol polymer in a solvent to form a solution and applying the solution to the substrate. The solution is dried to form a barrier layer on the substrate. The barrier layer is continuous, relatively thin, and has a consistent thickness throughout the barrier layer, yet provides improved barrier properties. The methods can include using water-impermeable interior and exterior layers for preventing liquid water and water vapor from negatively affecting the functioning of the barrier layer, and an adhesive layer for reducing flex cracking failure of the barrier layer.

### CROSS-REFERENCE TO RELATED APPLICATION

The present application claims the benefit of U.S. Provisional Patent Application No. 62/097,971 filed Dec. 30, 2014, which is incorporated herein by reference in its entirety.

### FIELD

The present subject matter relates to methods of forming barrier layers and barrier constructions incorporating such barrier layers that are suitable for restricting gas permeation through the barrier layer.

### BACKGROUND

Barrier coatings and layers have been included in the packaging of various air-sensitive or liquid-sensitive products to protect them from environmental gases and liquids, such as oxygen, water vapor in the atmosphere, or chemicals used in the processing, handling, storage and use of the products. A number of packaging applications, such as food, electronics, pharmaceutical, toothpaste, etc., require packaging having a relatively low Oxygen Transmission Rate (“OTR”) and/or a Water Vapor Transmission Rate (“WVTR”). Also, certain display devices, such as liquid crystal displays, light-emitting devices and light-emitting polymers require packaging that has very low OTR and WVTR.

Plastic films are often used in product packaging to protect the product from being exposed to high levels of gas and/or liquid. But, the gas and liquid permeation resistance of the plastic films used are not always sufficient to provide the desired level of protection.

In circumstances where improved gas barrier properties have been desired, the packages typically have been made from halogen-containing material. An example of a material used in such applications is polyvinylidene chloride (PVDC) film. Although use of that material is satisfactory in many regards, films containing halogens such as chloride and bromide are difficult and costly to recycle. In fact, with increasing environmental awareness, many regulations prohibit the disposal of halogens; thereby further increasing the inconvenience and/or cost of handling used barrier products containing halogens.

In order to improve the barrier characteristics of generally available plastic films, coatings have been applied to plastic substrates to decrease the gas and liquid permeability. For example, opaque, metalized plastic films have been used, but they are relatively expensive and are not transparent and therefore not suitable for all packaging types. As an alternative, transparent SiOx-coated plastic films may sometimes be used, but the cost of SiOx-coated plastic films is often too high for many commercial applications. Plastic films which are vacuum-coated with other inorganic materials, such as aluminum, AlO_{X}, SiO_{X}N_{Y} and Si₃N₄ also have been suggested as reducing the oxygen permeability and water vapor permeability of plastic films. Prior artisans have also investigated the use of other agents or materials in place of halogens, such as ethylene vinyl alcohol (EVOH). However, the coating weight of EVOH necessary to provide sufficient barrier properties is relatively high and thus expensive.

Furthermore, typically barrier layers have conventionally been formed by extrusions, and are relatively thick, e.g. greater than 10 microns (μm), are non-uniform in thickness, and are prone to flex-crack failure. As used herein, “flex-crack failure” or “flex cracking” refers to a phenomenon where a thin continuous barrier layer breaks, cracks, or otherwise degrades when subjected to deformation or flexure, such that voids, apertures, pathways, channels or other types of routes are formed in the barrier layer so that gas and/or liquids more readily pass through the barrier film from one surface to another and the barrier properties of the layer are degraded and show an increased OTR and/or WVTR. As used herein, “continuous” or “substantially continuous” layer means a layer that is substantially free of voids, apertures, or channels through the layer.

Other problems arise when an air-sensitive material is packaged in a container. Many of these materials are subject to degradation upon exposure to one or more components of air (e.g. nitrogen gas, oxygen gas, hydrogen gas) such that the material becomes unsuitable for its intended purpose. Some of these materials are sensitive to oxygen (e.g. products for human sustenance such as wine, tomato sauce, etc.) such that the materials oxidize upon exposure to oxygen gas. Once oxidation begins, these beverage and food products may lose their palatability for human consumption, which can affect the shelf life of the product. Such materials or products that are sensitive to one or more components of air will be referred to herein as “air-sensitive,” “oxygen-sensitive,” “degradable,” material or product.

In order to reduce exposure of the material to air, and particularly to oxygen gas, certain air-sensitive material is often packaged in sealed air-tight containers in order to prevent excessive exposure to air that may cause the material to become unsuitable for its intended purpose. However, when the material is filled into a container and sealed, a certain amount of air may be introduced into the container. The presence of air in a sealed container may result from gas being trapped in the container as the material is sealed into the container, from gas passing through the walls of the container, or from gas passing through the seals of the container. The amount of air in the container is referred to herein as “headspace gas” (HSG) and may include head space oxygen (HSO).

In order to address these concerns and to reduce the likelihood of degradation of the material, several techniques have been used to limit or reduce the amount of HSG in the containers. These techniques have included various processes including making adequate seals for the containers so that gas cannot enter the container through the seals; using containers with increased gas barrier properties so that gas cannot enter the container through the walls of the container; drawing a vacuum in the container during the sealing process; or placing the containers in an inert atmosphere during the sealing process in order to reduce the amount of HSG in the container.

In circumstances where a vacuum or an inert atmosphere have been used, an increase in cost is typically associated with such packaging procedures, which thereby increases the overall cost of the product. Further, drawing a vacuum may be unsuitable for certain delicate material that could be damaged as a result of drawing a vacuum in the container.

However, even when using these materials and packaging techniques, material that is sealed in an air-tight container (even those packaged under vacuum or in an inert atmosphere) may nevertheless be exposed to air as a result of the characteristics of the air-sensitive material, among other reasons, which can still result in degradation of the material. More specifically, efforts to reduce the amount of HSG in a container may not entirely prevent exposure of the air-sensitive material to gas, including oxygen gas. This phenomenon can result from gas being present in the material itself that is sealed in the container. That is, the air-sensitive material may include gas, which may be dissolved, dispersed or otherwise contained therein. For example, gas sealed in a container may include air that is dispersed in tomato sauce during a mixing or cooking process.

This dissolved or dispersed gas (DG) may include dissolved or dispersed oxygen (DO). After packaging procedures in which substantially all of the HSG is eliminated from the interior of the sealed container, and after forming the container from highly gas-impermeable material, DG may nevertheless come out of, or simply separate from the material and may aggregate into a bubble or other form that is separate and distinct from the material. When the DG aggregates together within the sealed container, the DG may increase the amount of HSG. Therefore, conventional packaging materials and techniques may altogether fail to address the problem of DG being present in the material and accumulating in the sealed container. More specifically, drawing a vacuum or packaging a material in an inert atmosphere, or using highly gas impermeable containers, does not reduce the amount of HSG due to the accumulation of DG that is present in a material sealed in a container.

Accordingly, there exists a need for an improved barrier layer and methods of forming such barrier layers that are capable of limiting the amount of air reaching an air-sensitive material sealed in a container.

### SUMMARY

The difficulties and drawbacks associated with previously known methods and barrier layers are addressed in the present barrier layers and related combinations and methods.

The present subject matter relates to methods of forming a barrier layer or barrier coating which can be used to reduce the OTR through barrier constructions that incorporate such barrier layer or coating, and that can be used to reduce the amount of gas on one side of the barrier construction.

In one aspect, the present subject matter provides a method of forming a layer of highly amorphous vinyl alcohol polymer on a substrate. The method comprises dissolving highly amorphous vinyl alcohol polymer in solvent to form a solution, applying the solution to the substrate, and substantially removing solvent from the solution to produce a layer of highly amorphous vinyl alcohol polymer on the substrate.

In another aspect, the present subject matter provides a method of improving gas barrier properties of a film. The method includes providing a solution of highly amorphous vinyl alcohol polymer dissolved in a solvent and applying the solution on a film to thereby form a coating layer on the film. The method includes evaporating the solvent from the coating layer to form a dry barrier coating of highly amorphous vinyl alcohol polymer on the film. The barrier coating has a coating weight of about 0.50-85 g/m².

In another aspect, the present subject matter provides method of making a gas barrier construction configured to limit the amount of gas transmitted through the construction from a first face of the gas barrier construction to a second face of the gas barrier construction. The method includes providing a first moisture impermeable film layer having a first surface and an oppositely directed second surface. The method includes applying a solution comprising highly amorphous vinyl alcohol polymer dissolved in a solvent to the second surface of the outer moisture impermeable film to thereby form a coating layer. The coating layer is dried by substantially removing the solvent from the coating layer to thereby form a barrier layer. The method includes disposing an adhesive layer on a side of the barrier layer opposite from the first moisture impermeable film layer and positioning a second moisture impermeable film layer on a side of the adhesive layer opposite from the barrier layer to thereby form the gas barrier construction. The first surface of the first moisture impermeable film layer is directed toward the first face of the gas barrier construction. The second moisture impermeable film layer includes a surface that is oppositely directed from the adhesive layer and is directed toward the second face of the gas barrier construction.

As will be realized, the subject matter described herein is capable of other and different embodiments and its several details are capable of modifications in various respects, all without departing from the claimed subject matter. Accordingly, the drawings and description are to be regarded as illustrative and not restrictive.

### BRIEF DESCRIPTION OF THE DRAWINGS

These, as well as other features, aspects, and advantages of the present subject matter, will be more completely understood and appreciated by referring to the following more detailed description of the exemplary embodiments of the present subject matter in conjunction with the accompanying drawings.

FIG. 1 is a schematic, perspective view of a multi-layer barrier construction in accordance with the present subject matter.

FIG. 2 is a schematic, perspective view of another multi-layer barrier construction in accordance with the present subject matter.

FIG. 3 is a schematic, perspective view of still another multi-layer barrier construction in accordance with the present subject matter.

FIG. 4 is a schematic, cross-sectional view of a container in accordance with the present subject matter.

FIG. 5 is a schematic, cross-sectional view of another container in accordance with the present subject matter.

FIG. 6 is a schematic, perspective view of a combination of articles in accordance with the present subject matter.

FIG. 7 is a graph showing oxygen barrier performance at 23° C. under varying humidity levels.

FIG. 8 is a graph showing water solubility of a particular resin composition.

FIG. 9 is a schematic view of a method of forming a barrier layer and related barrier construction in accordance with the present subject matter.

FIG. 10 is a schematic view of another method of forming a barrier layer and related barrier construction in accordance with the present subject matter.

### DETAILED DESCRIPTION OF THE EMBODIMENTS

Barrier layers formed by methods in accordance with the present subject matter are configured to reduce the OTR of barrier constructions into which they are incorporated. As will be described, the barrier layer comprises a highly amorphous vinyl alcohol polymer that is an effective gas barrier when in a dry form and subject to conditions of less than 65% relative humidity. As such, the barrier layer has usefulness as a single coating applied to any substrate that has some level of resistance to moisture permeation. In combination, the barrier layer and moisture impermeable substrate construction provide a barrier to the transmission of both oxygen gas and liquid and vaporized water through the construction.

The highly amorphous vinyl alcohol polymer can be dissolved in a solvent and then wet coated on the substrate. The coating can be dried to form a substantially continuous barrier layer on the substrate having a highly uniform thickness.

In one embodiment, when a barrier construction including such a barrier layer is incorporated as part of a container housing an air-sensitive material, the barrier construction is configured to restrict the amount of oxygen and/or liquid water and water vapor that reaches the air-sensitive material from outside the container, and/or may reduce the amount of HSG on one side of the barrier construction. Accordingly, the barrier construction may thereby prevent degradation of air-sensitive material (e.g. oxygen-sensitive material) that is sealed in such containers, among other benefits, by reducing the amount of oxygen and/or water vapor that passes through the barrier construction. Alternatively, the barrier construction can be used in a situation where it is desirable to retain an amount of gas on one side of the barrier construction. This can be accomplished by using the construction to limit gas from passing through the barrier construction.

The subject matter described herein provides methods of making barrier layers and multi-layer barrier constructions. In one embodiment, a method includes forming a barrier coating or layer comprising a barrier material on a filmic substrate. In one aspect, the filmic substrate is a protective layer, wherein the protective layer is impermeable to liquid water and has a relatively low WVTR, which is thereby capable of maintaining the barrier layer in a dry state and protecting the barrier layer from conditions of more than 65% relative humidity. The barrier coating is protected from contact with liquid water and water vapor (collectively referred to as “water” or “moisture”) by the protective layer. A second protective layer that is also impermeable to liquid water and has a relatively low WVTR may be applied to a side of the barrier coating opposite from the first protective layer to further protect the barrier coating from moisture.

The barrier coating may be buttressed by an adhesive layer on one or two sides of the barrier layer. The adhesive layer(s) can be in direct contact with the barrier layer. In this way, the adhesive layer can provide some resistance for the barrier layer to flex cracking. When the adhesive layer includes a highly extensible material, such as a pressure sensitive adhesive, the adhesive layer can provide impact dampening protection to the relatively thin barrier layer, thus maintaining the barrier properties of the barrier layer.

The barrier layer formed by methods in accordance with the present subject matter is capable of limiting the amount of oxygen that can pass through the barrier layer and can improve the barrier properties of the substrate to which it is applied. When the barrier layer is used in a barrier construction as described herein, the barrier construction is able to limit the amount of oxygen and water passing through the construction. In several embodiments, the barrier construction may also be capable of providing the novel characteristic of reducing an amount of air (including oxygen gas) present on one side of the barrier construction, wherein the air on one side of the barrier construction can be air in an interior of a container (e.g. HSG including HSO sealed inside a container).

The barrier construction can be incorporated into any type of construction. For example, the barrier construction can be included in a container, and may be useful in containers for materials that are subject to degradation upon being exposed to various components of air, such as for example oxygen gas. Designation of material as being air-sensitive or otherwise, should not be construed to limit the scope of the present subject matter, as it will be appreciated that the barrier construction can be used in packaging for material that is not subject to degradation upon being exposed to various components of air.

In certain embodiments, the barrier construction is configured to seal to itself thereby defining the entirety of a sealed container, or it can be incorporated as a portion of sealed containers, such as a lid sealed on a tray. In these embodiments, the barrier construction may be configured to prevent the material contained therein from being released to the exterior of the container. In these various aspects, the barrier construction may also be capable of decreasing an amount of gas, such as oxygen and other gases that may be present in an interior of the sealed container and which may be present due to the accumulation of DG and DO.

The barrier construction can be alternatively used to separate one material from another. For example, the interior of a tube, bottle, or other type of container can be separated into two or more portions by the barrier construction. A first portion of the container can contain an air-sensitive material. In one aspect, the barrier construction is configured so that it may reduce the amount of air in the first portion of the container that houses the air-sensitive material, such as when the contents of the container include a liquid, such as an aqueous mixture, solution, or system.

This novel functioning of the barrier construction for reducing the amount of air on one side of the barrier construction, may decrease or eliminate the need for using an inert atmosphere or for drawing a vacuum when packaging air-sensitive material. Further, an amount of air that may be trapped inside the container—either when the container is sealed (e.g. HSG and HSO) or that which is present in the material itself (e.g. DG and DO)—may be reduced.

Before describing the various methods of making the barrier layer and related barrier constructions, the barrier constructions and various layers themselves will first be described.

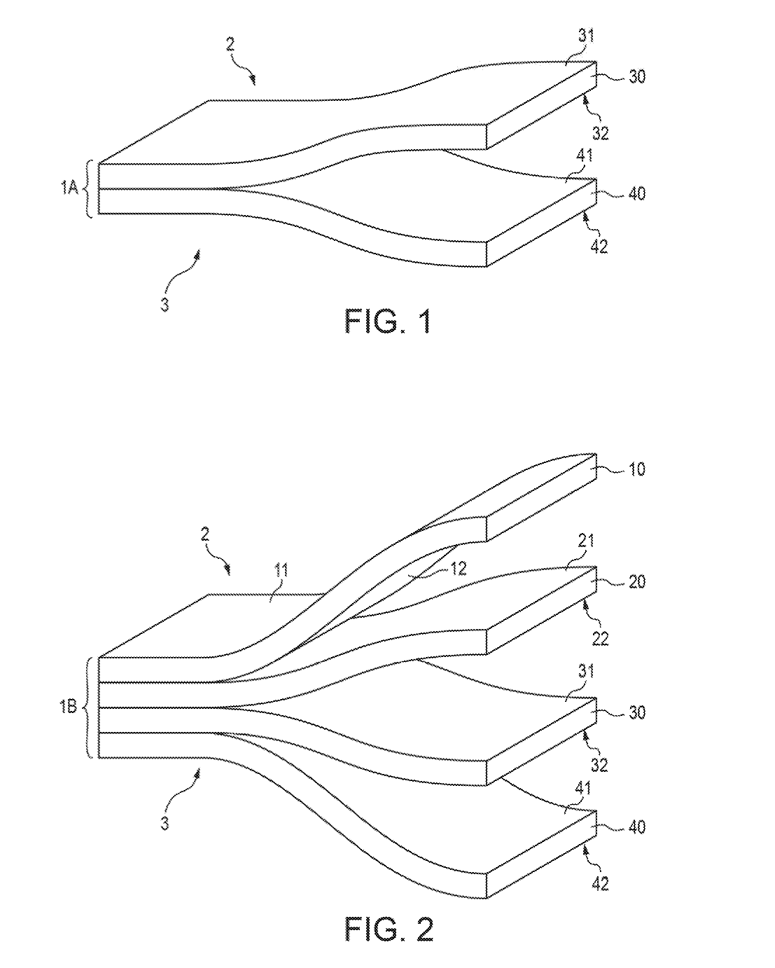

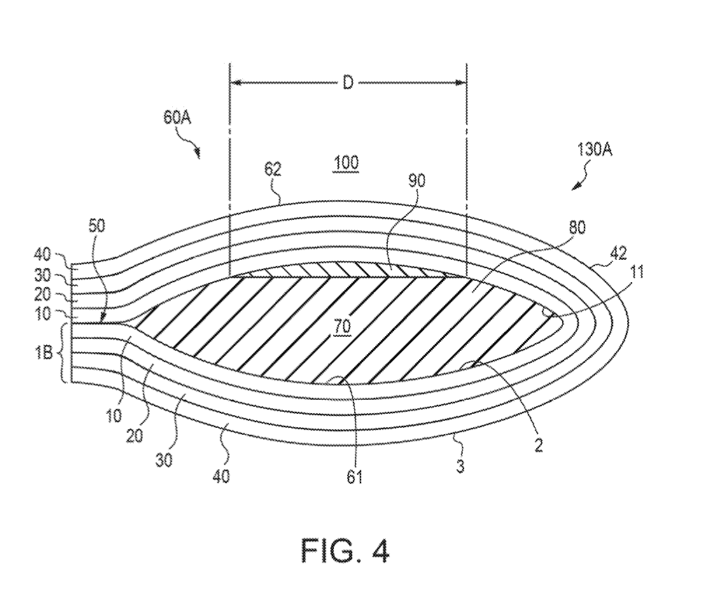

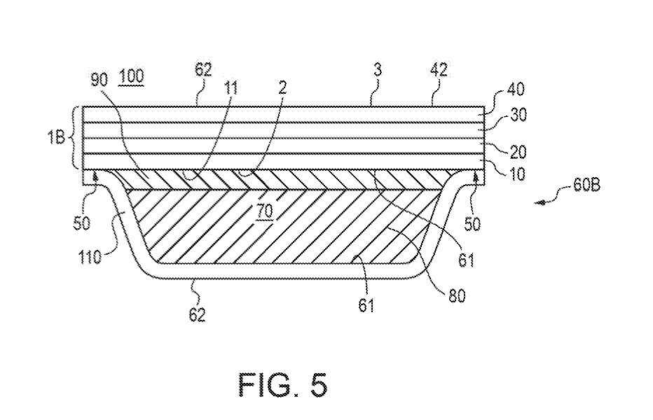

In one embodiment and in reference to FIGS. 1-5, the barrier construction comprises a multi-layer construction, shown for example as 1A, 1B, and 1C, defining a first side 2 and an oppositely directed second side 3. The multi-layer construction can include two or more layers as shown for example in FIGS. 1-5. However, it will be understood that the multi-layer construction can include more or less, and different layers than that depicted in FIGS. 1-5. From the first side 2 to the second side 3, the multi-layer construction can include a water-impermeable layer 10, an adhesive layer 20, a barrier layer 30, an optional second adhesive layer 170, and a water-impermeable layer 40. When the barrier construction is incorporated as part of a container such as containers 60A and 60B as in FIGS. 4-5, the first side 2 of the multi-layer construction may face an interior 70 of the container and the second side 3 may face an exterior 100 of the containers 60A and 60B. For example and in reference to FIGS. 4-5, the protective layer 10 is situated closest to the interior 70 (i.e. inner region) of the containers 60A and 60B and the protective layer 40 may be situated furthest from the interior 70 of the containers 60A and 60B. In this respect, the protective layer 10 is also referred to herein as the “interior layer” and the protective layer 40 is also referred to herein as the “exterior layer.” However, the designation of layers 10, 40 as “interior” and “exterior” respectively, is simply for convenience and is not meant to limit positioning of the two layers 10, 40 in a specific orientation relative to a container. In fact, the multi-layered construction can be reversed in relation to the container, such that layer 40 is positioned closer to the interior 70 of a container while layer 10 is positioned further from the interior 70.

For example, the multi-layer construction may be used to retain an amount of gas inside a container, wherein the first side 2 of the multi-layer construction may face an exterior 100 of the container and the second side 3 may face the interior 70 of the container. Where the multi-layer construction includes a protective layer 10 and a protective layer 40, the protective layer 40 may be situated closer to the interior 70 (i.e. inner region) of the container and the protective layer 10 may be situated further from the interior 70 of the containers 60A, 60B.

In accordance with the present subject matter, the multi-layer construction can be used either for protecting and/or housing an air-sensitive material or for housing a non-air-sensitive material.

As seen in FIG. 1, the multi-layer construction 1A includes an exterior layer 40 and a barrier layer 30 formed thereon. The barrier layer 30 defines a first side 31 and a second side 32. The exterior layer 40 defines a first side 41 and a second side 42. The second side 32 of the barrier layer is mated (i.e., directly abutting) with the first side 41 of the exterior layer 40.

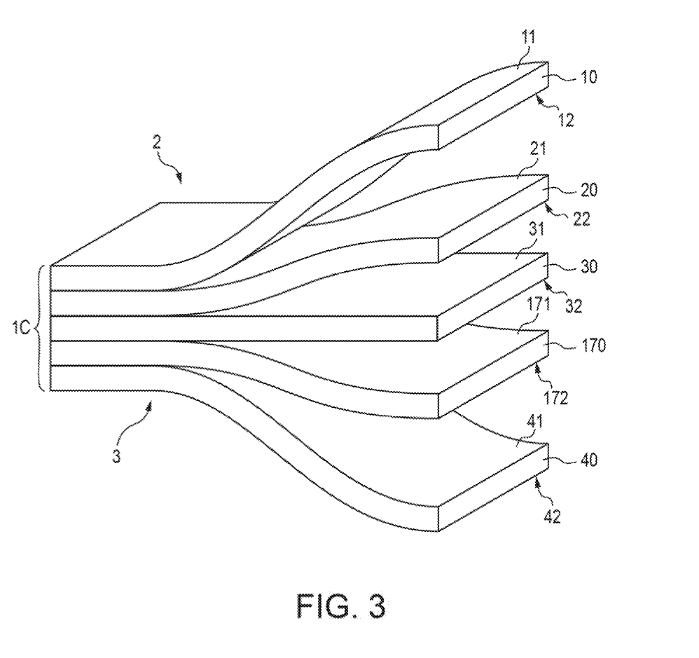

As shown in FIGS. 2-3, the multi-layer constructions 1B, 1C further include an interior layer 10 including a first face 11 and an oppositely directed second face 12; an adhesive layer 20 including a first face 21 and an oppositely directed second face 22; the barrier layer 30 including a first face 31 and an oppositely directed second face 32; and the exterior layer 40 including a first face 41 and an oppositely directed second face 42. As shown in FIG. 2, the second face 12 of the interior layer 10 is mated with the first face 21 of the adhesive layer 20; the second face 22 of the adhesive layer 20 is directly abutting the first face 31 of the barrier layer 30; and the second face 32 of the barrier layer 30 is directly abutting the first face 41 of the exterior layer 40. FIG. 3 additionally shows a second adhesive layer 170 having a first face 171 and a second face 172 positioned between the barrier layer 30 and the exterior layer 40, wherein the first face 171 of the second adhesive layer 170 is mated with the second face 32 of the barrier layer 30 and the second face 172 of the second adhesive layer 170 is mated with the first face 41 of the exterior layer 40.

It will be understood that the multi-layer constructions can be differently constructed and can include more or less layers and other layers than that depicted in the figures and described in association with the representative constructions 1A, 1B, and 1C. For example, in one embodiment the multi-layer construction does not include the exterior layer 40, which may in certain embodiments be water-impermeable. Further, other various layers can be incorporated between the layers 10, 20, 30, 170, 40 depicted in the figures, for example. It will also be understood that the various layers 10, 20, 30, 170, 40 of the barrier construction are not necessarily smooth, continuous, and of uniform thickness as depicted in the figures, but may be rough or textured, may be discontinuous, such as having voids therein, patterned, intermittent, or layered, and may be of varying thicknesses as desired for certain applications.

The multi-layer construction 1B shown in FIGS. 4-5 is similar to the multi-layer construction 1B as shown in FIG. 2. Accordingly, the description of the multi-layer construction for FIGS. 4-5 is omitted because it will be understood that such construction includes the features as described for the multi-layer construction in FIG. 2.

In the embodiment shown in FIG. 4, the barrier construction is a multi-layer construction 1B folded upon itself and sealed. A seal 50 is shown to be formed such that the interior layer 10 is sealed to itself to thereby form a container 60A defining an interior 70. However, it will be understood that the seal 50 can be formed between other various layers. As shown in FIG. 4, the interior 70 of the container 60A is filled with an air-sensitive material 80, and contains air 90. The air 90 included in the interior 70 of the container 60A can include an amount of HSG, which may increase over time due to the accumulation of DG that may be present in the air-sensitive material 80. The gas 90 located in the interior 70 of the container 60A is of a certain amount indicated by a diameter (D) of the HSG air bubble schematically shown in FIG. 4, which may be reduced by incorporating the multi-layer construction as part of the container 60A. As shown in FIG. 4, the seal 50 created between various portions of the interior layer 10 prevents the material 80 from escaping from the interior 70 of the container 60A to the exterior 100 of the container. In this embodiment, the container 60A may be a flexible bag-type container as shown. However, it will be understood that the container can take on any shape or form, can be rigid, and is not particularly limited by the present subject matter.

In the embodiment shown in FIG. 4 the multi-layer construction 1B defines a container 60A, such that the protective layer 10, which in this embodiment is water-impermeable, defines an inner most layer of the multi-layer construction that is situated closest to the interior 70 of the container 60A. Accordingly, the first face 11 of the interior layer 10 defines the first side 2 of the multi-layer construction 1B and also defines the interior surface 61 of the container 60A. Similarly, the second face 42 of the exterior layer 40 corresponds to the second side 3 of the multi-layer construction and also defines the exterior surface 62 of the container 60A. It will be understood that both of the first side 2 of the multi-layer construction and the interior surface 61 of the container 60A are not necessarily defined by the first face 11 of the interior layer 10, but that one or more of the first side 2 of the multi-layer construction and the interior surface 61 of the container 60A can be defined by other and different layers that may be incorporated into the multi-layer structure 1B. Similarly, it will also be understood that both of the second side 3 of the multi-layer construction and the exterior surface 62 of the container 60A are not necessarily defined by the second face 42 of the exterior layer 40, but that one or more of the second side 3 of the multi-layer construction and the exterior surface 62 of the container 60A can be defined by other and different layers that may be incorporated into the multi-layer structure 1B.

In another embodiment and in reference to FIG. 5, the barrier construction 1B is a multi-layer construction such as the previously described construction 1B, that comprises a portion of a container 60B. It will be appreciated that the container 60B shown in FIG. 5 can house a material 80 in a similar way to the container 60A depicted in FIG. 4, and may include HSG 90 and/or DG sealed therein.

As shown, the multi-layer construction 1B in FIG. 5 is used as a lid that is sealed to a tray 110 portion of the container 60B, wherein a seal 50 is formed between the tray 110 and the multi-layer construction. It will be understood that the configuration of the container 60B including the multi-layer construction, can include various sizes and shapes for the multi-layer construction and for the tray 110 portion of the container 60B. For example, rather than, or in addition to including a tray 110, the container can comprise a bottle, a bag, a box, or the like having the multi-layer construction in accordance with the present subject matter sealed over an aperture therein.

As will be understood and in reference to FIG. 5, air located in the interior 70 of the container 60B may be of a certain amount, which may be reduced by using the multi-layer construction as part of the container 60B. As shown in FIG. 5, the multi-layer construction again includes an interior layer 10 defining a first face 11 that defines the first side 2 of the multi-layer construction. The first face 11 of the interior layer 10 is in direct communication with the interior 70 of the container 60B. The multi-layer construction also includes an adhesive layer 20, a barrier layer 30, and an exterior layer 40 which in this embodiment is water impermeable, defining a second face 42 that in turn defines the second side 3 of the multi-layer construction. As shown, an interior surface 61 of the container 60B is partially defined by both the first side 2 of the multi-layer construction and the first face 11 of the interior layer 10. The exterior surface 62 of the container 60B is partially defined by both the second side 3 of the multi-layer construction and the second face 42 of the exterior layer 40.

As shown in FIG. 5, the multi-layer construction 1B and tray 110 together define container 60B having an interior 70 suitable for holding air-sensitive material 80 or other material. The seal 50 created between the multi-layer construction and the tray 110 portion of the container 60B restricts egress of the material 80 from the interior 70 of the container 60B to the exterior 100 of the container 60B.

It will be appreciated that the multi-layer construction 1B depicted in FIGS. 4-5 can include more or less layers as described herein, and can be oppositely situated in relation to the interior 70 of the containers 60A, 60B.

In accordance with the present subject matter, several embodiments include intimate contact between the adhesive layer 20 and the barrier layer 30, wherein other layers that may be included in the multi-layer constructions 1A, 1B, 1C, are not located between the adhesive layer 20 and the barrier layer 30. In this regard, several embodiments of the present subject matter include the adhesive layer 20 disposed directly on, directly contacting, and/or directly abutting the first face 31 of the barrier layer 30. Where a second adhesive layer 170 is included, the second adhesive layer may also directly abut the second face 32 of the barrier layer 30.

While not being bound to any particular theory, it is believed that the intimate contact between the adhesive layer 20 and the barrier layer 30 promotes the ability of the multi-layer construction to decrease an amount of air 90 located in the interior 70 of a container, such as the containers 60A and 60B, and/or to decrease an amount of air located at the first side 2 of the multi-layer construction. It is believed that intimate contact between the adhesive layer 20 and the first face 31 of barrier layer 30 may cause the barrier layer 30 to function as a one-way molecular sieve, thereby enabling gas to be transported through the multi-layer construction only from an interior 70 to an exterior 100 of the container, while at the same time preventing gas from being transported from the exterior 100 to the interior 70 of the container.

More specifically, it is believed that the barrier layer 30 becomes selectively permeable in only one direction (i.e. from the first face 31 to the second face 32) while acting as a barrier in the other direction (i.e. from the second face 32 to the first face 31). Gas can then be transmitted through the barrier layer 30 from the first face 31 (i.e. “inner face”), which contacts the adhesive layer 20, to the second face 32 (i.e. “outer face”). The intimate contact between the adhesive layer 20 and the inner face 31 of the barrier layer 30 is believed to at least partially produce this functioning.

It is alternatively theorized that the intimate contact between the adhesive layer 20 and the first face 31 of barrier layer 30 may cause the barrier layer 30 to function as a one-way air absorber, wherein gas on the first side 2 of the multi-layer construction may be absorbed to a certain extent by the barrier layer 30 to thereby reduce the amount of gas 90 in the interior 70 of the container.

Without the intimate contact between the adhesive layer 20 and the barrier layer 30, it is believed that the barrier layer 30 would not act as a one-way sieve to allow gas to be transported through the barrier layer, or to act as a one-way gas absorber. Rather, the barrier layer 30 would act as it normally should—that is, as a two-way gas barrier that restricts the transport of gas through the barrier layer 30 in both directions, or not as a gas absorber, respectively. More specifically, in certain instances if the adhesive layer 20 were not in intimate contact with the barrier layer 30, it is believed that an amount of gas 90 trapped in an interior 70 of a sealed container would not be reduced, but would be maintained at the original amount. Further, it is believed that any DG that may be released from a material may therefore increase the amount of HSG located in the interior 70 of the container. It is also believed that direct contact between the adhesive layer 20 and the barrier layer 30 provides protection against flex cracking in the barrier layer 30.

These and other aspects of the various layers of the multi-layer construction are described in more detail below.

### Barrier Layer

In accordance with the present subject matter the barrier layer 30 is configured so that it may inhibit the transmission of gas from one side of the barrier construction to the other and/or reduce the amount of gas located at the first side 2 of the multi-layer construction.

As shown in the figures, the barrier layer 30 includes a first face 31 (e.g. the inner face) that faces the interior 70 of the container, and is closer to the first side 2 of the multi-layer construction than the second face 32. This inner face 31 is in intimate contact with the adhesive layer 20. The second face 32 (e.g., outer face) is oppositely directed from the inner face 31 and faces the exterior 100 of the container, or is closer to the second side 3 of the multi-layer construction than the inner face 31. In one aspect, the outer face 32 is in intimate contact with the water-impermeable exterior layer 40. However, it will be understood that the outer face 32 of the barrier layer 30 may not be in intimate contact with the exterior layer 40, wherein other and various layers are inserted therebetween such as for example a second adhesive layer 170.

In one embodiment, barrier layer 30 comprises an amorphous vinyl-alcohol copolymer resin. Amorphous indicates a condition in which polymer molecules are randomly structured with relatively low percentage crystallinity. In one embodiment, the barrier layer 30 comprises a highly amorphous vinyl alcohol polymer having an average level of crystallinity of less than about 35%, less than about 25%, or less than about 20%.

The highly amorphous vinyl alcohol polymer can comprise or consist of a vinyl alcohol homopolymer. In another example, the highly amorphous vinyl alcohol polymer can comprise or consist of a vinyl alcohol copolymer. In yet another example, the vinyl alcohol polymer can comprise or consist of an acetoacetic ester group-containing vinyl alcohol copolymer, or a vinyl alcohol copolymer which has been partially acetalized, or a vinyl alcohol copolymer which comprises vinyl alcohol units having a 1, 2 diol structure, or any combination thereof. In one embodiment the highly amorphous vinyl alcohol copolymer can be fully or partially saponified, wherein all or some of the ester groups in the polymer have been substituted with hydroxyl groups. The degree of saponification of the highly amorphous vinyl alcohol copolymer can be from about 50 mol % to about 98 mol %.

An example of a suitable highly amorphous polyvinyl alcohol polymer for use in the barrier layer 30 is Nichigo G-Polymer, including grades AZF8035W, OKS-1024, OKS-8089, OKS-8041, OKS-8118, OKS-6026, OKS-1011, OKS-8049, OKS-1028, OKS-1027, OKS-1109, OKS-1081, and OKS-1083 provided by Nippon Gohsei Synthetic Chemical Industry, Osaka Fukoku Seimei Building, 2-4, Komatsubara-cho, Kita-ku, Osaka 530-0018, Japan.

Nichigo G-Polymer is believed to be a resin composition, which comprises: (A) a PVA resin having a 1,2-diol structural unit represented by the following general formula (1):

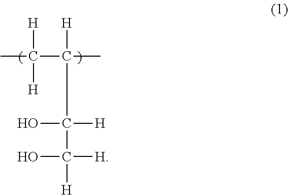

and having a saponification degree of 80 to 97.9 mol %; and (B) an alkylene oxide adduct of a polyvalent alcohol containing 5 to 9 moles of an alkylene oxide per 1 mole of the polyvalent alcohol. Nippon Gohsei also refers to Nichigo G-Polymer by the chemical name, butenediol vinyl alcohol (BVOH). Additional details of this material are described in U.S. Pat. No. 8,026,302.

Performance characteristics of Nichigo G-polymer are as follows.

TABLE 1
Oxygen Barrier Performance

| | | Normalized with |
|---|---|---|
| Samples | cc 20 um/m² day atm | Nichigo G-Polymer |
| Nichigo G-Polymer | 0.0023 | 1 |
| Fully saponified PVOH | 0.0050 | 2 |
| EVOH 29 mol % | 0.07 | 30 |
| EVOH 44 mol % | 1.3 | 600 |
| Nylon 6 | 76 | 35,000 |
| Polypropylene | 3,900 | 1,700,000 |

Table 1 shows oxygen barrier performance in dry conditions at 20° C. of a film formed from Nichigo G-polymer grade OKS-8049, compared to other polymer films.

TABLE 2
Hydrogen Barrier Performance

| Sample | cc 20 um/m² day atm |
|---|---|
| Nichigo G-Polymer | <3 |
| EVOH 29 mol % | 26 |
| EVOH 44 mol % | 440 |
| Nylon 86 | 900 |
| Nylon 11 | 5,600 |

Table 2 shows hydrogen barrier performance in dry conditions at 41° C. of a film formed from Nichigo G-polymer grade OKS-8049, compared to other polymer films.

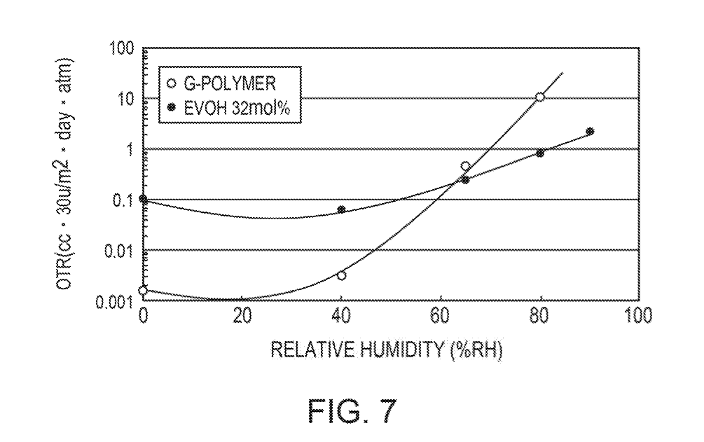

FIG. 7 shows oxygen barrier performance at 23° C. under varying humidity levels of a multi-layer film having one layer of Nichigo G-polymer grade OKS-8049 and a layer of polypropylene, compared to a multi-layer film having one layer of ethylene vinyl alcohol (EVOH) and a layer of polypropylene.

TABLE 3
Vapor Permeability Performance

| | | 40° C. | 40° C. |
|---|---|---|---|
| | | 60% RH | 80% RH |
| | | g 30 | g 30 |
| Samples | | um/m² day | um/m² day |
| Nichigo | Solution cast film | 7.5 | 480 |
| G-Polymer | Extrusion cast film | 6.3 | 470 |
| Fully saponified | Solution cast film | 4.9 | 350 |
| PVOH | | | |
| LDPE | Extrusion cast film | 15 | 20 |

Table 3 shows vapor permeability at 40° C., and at 60% and 80% relative humidity, of a 30 μm thick film formed from Nichigo G-polymer grade OKS-8049, compared to other 30 μm thick polymer films.

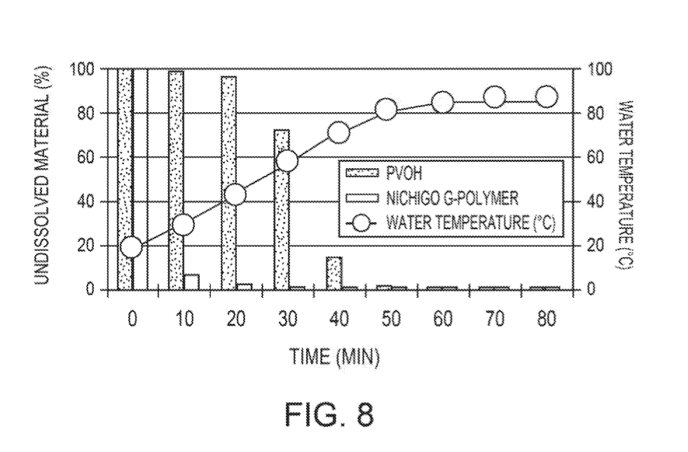

FIG. 8 shows water solubility according to water temperature and time of Nichigo G-polymer at 6% concentration, compared with fully saponified polyvinyl alcohol (PVOH) at 6% concentration.

In one aspect, the barrier layer 30 comprises a dry highly amorphous vinyl alcohol polymer. As used herein, “dry” means that solvent (e.g. water) content is substantially removed from the solution, leaving the highly amorphous vinyl alcohol polymer in a dry state and substantially non-tacky, and under conditions of less than 65% relative humidity. Highly amorphous vinyl alcohol polymer is soluble in water but when dry and under conditions of less than 65% relative humidity, the highly amorphous vinyl alcohol polymer normally provides excellent two-way gas barrier properties superior to EVOH or PVOH at the same coating weight. Accordingly, the interior layer 10 and the exterior layer 40 are included in several aspects as protective layers in the multi-layer construction to maintain the highly amorphous vinyl alcohol polymer in a dry state and under conditions of less than 65% relative humidity so that the gas barrier properties of the barrier layer 30 are not affected by water or moisture from the interior 70 or exterior 100 of the container. In one aspect, the barrier layer 30 comprises the highly amorphous vinyl alcohol polymer in dry form and which is substantially non-tacky. The highly amorphous vinyl alcohol polymer is a biodegradable thermoplastic that can be extruded, is relatively transparent to visible light with a percent haze of the polymer less than 30%, has a relatively low level of UV light transmittance of less than 15%, and is capable of dissolving in water.

Reducing the amount of air located at the first side 2 of the multi-layer construction may be accomplished by applying adhesive directly to the barrier layer 30. While not being bound to any particular theory, it is believed that the barrier layer 30 comprising the highly amorphous vinyl alcohol polymer is activated by direct contact between the first face 31 of the barrier layer with the adhesive in the adhesive layer 20, to thereby provide one-way barrier properties (either as a one-way molecular sieve or as a one-way gas absorber) for the multi-layer construction. By “one-way barrier properties” it is meant that various components of air (such as oxygen gas and hydrogen gas) are substantially prevented from transmitting through the barrier layer 30 in a direction from a face (e.g. the second face 32) of the barrier layer 30 that is not in intimate contact with the adhesive layer 20 to a face (e.g. the first face 31) of the barrier layer 30 that is in intimate contact with the adhesive layer 20, however at the same time, various components of air are capable of being transmitted through, or absorbed by, the barrier layer 30 in a direction from the face (e.g. the first face 31) of the barrier layer 30 that is in intimate contact with the adhesive layer 20 to the face (e.g. the second face 32) of the barrier layer 30 that is not in intimate contact with the adhesive layer 20.

More specifically and for example, the amount of air located in the interior 70 of the container may be reduced, while air located at the exterior 100 is unable to enter the interior 70 of the container. This reduction in the amount of air located in an interior of a container is shown in a number of examples included herein. The examples include barrier constructions including HAVOH, which are used to house liquid contents. Accordingly, it is believed that the barrier layer 30 can provide one-way (interior 70 to exterior 100) air permeability or one-way absorption of air from the interior 70 of the container, while also providing one-way (exterior 100 to interior 70) barrier properties, to thereby reduce an amount of air on one side of the multi-layer constructions 1A, 1B, and 1C, e.g. in the interior 70 of the container.

In one aspect, the barrier layer 30 may be formed by combining highly amorphous vinyl alcohol polymer and water to form a barrier composition (also referred to herein as a “solution”), wherein the highly amorphous vinyl alcohol polymer is dissolved in water. The barrier composition may also include an additive such as glycerin, poly(ethylene oxide) (PEO), or a combination thereof for example, to enhance certain characteristics of the barrier composition or barrier layer. Glycerin can be included to enhance moisture receptivity. PEO can be included to enhance viscosity of the barrier composition for a particular coating application method, such as curtain coating to produce thicker layers greater than 4 g/m² for example. A suitable PEO can comprise Polyox WSR-750 provided by Dow Chemical Company, 2030 Dow Center, Midland, Mich. A barrier composition not including PEO, and therefore having a lower viscosity can be used for rotogravure or direct coating methods. Other additives can be included in the barrier composition as desired for adjusting characteristics of the barrier composition or barrier layer, such as the evaporation rate, viscosity, wettability, rheology, color, and the like. The barrier composition comprising highly amorphous vinyl alcohol polymer, optional additive, and water can be formed into the barrier layer 30 by drying the barrier composition/solution to substantially remove the water content. The amounts of highly amorphous vinyl alcohol polymer, optional additive, and water in the barrier composition are not particularly limited by the present subject matter as long as a barrier layer 30 once formed by removing the water content, is of proper thickness and is capable of providing sufficient barrier properties and optionally reducing an amount of gas at the first side 2 of the multi-layer constructions 1A, 1B, and 1C.

In this regard, the highly amorphous vinyl alcohol polymer can be included from about 75 weight percent (wt %) to about 100 wt % of the total combined weight of highly amorphous vinyl alcohol polymer and optional additive(s); and the additive(s) can be included from about 0 wt % to about 25 wt % of the total combined weight of highly amorphous vinyl alcohol polymer and additive(s). The amount of water is not particularly limited and can be added in an amount in order to achieve the desired viscosity of the barrier composition and as appropriate for certain techniques used for forming the barrier layer 30. In another aspect, a highly amorphous vinyl alcohol polymer is extruded by casting or blown into a film to form the barrier layer 30.

The average thickness of the dried barrier layer 30, which is formed by substantially removing the water content from the barrier composition, is not particularly limited by the present subject matter. Because the barrier layer 30 may be protected from water and humid conditions above about 65% relative humidity by one or more of the interior layer 10 and the exterior layer 40, both of which may in certain embodiments be water-impermeable, the barrier layer 30 can be a relatively thin layer while still being capable of maintaining adequate barrier properties. Further, where one or more adhesive layers are directly abutting the barrier layer 30, the adhesive layers protect the barrier layer 30 from flex-crack failure and may activate the barrier layer to reduce the amount of gas on one side of the constructions 1A, 1B, and 1C.

In one embodiment, the barrier layer 30 has an average thickness ranging from about 0.015 μm to about 12 μm or higher, or a coating weight ranging from about 0.1 g/m² to about 85 g/m² or higher. Average barrier layer thicknesses lower than 0.015 μm, or coating weights lower than 0.1 g/m², may not offer sufficient barrier properties for the multi-layered constructions 1A, 1B, and 1C such that an amount of air in an interior of a container is not reduced, while thicknesses greater than 12 μm, or coating weights greater than 85 g/m², may be subject to flex cracking. In one aspect, the barrier layer 30 is present at an average thickness of about 0.15 μm to about 0.30 μm, and particularly at about 0.18 μm; or a coating weight from about 1 g/m² to about 2 g/m², and particularly at about 1.2 g/m². In another aspect, the barrier layer is present at an average thickness of about 0.1 g/m² to about 10 g/m².

When formed into a dry film having sufficient thickness, the highly amorphous vinyl alcohol polymer layer can have an oxygen transmittance rate of less than 0.0023 cc/m²/day at 20° C., 1 atm, and 0% relative humidity.

The barrier layer 30 may comprise other barrier materials such as polyvinyl alcohol (PVOH), ethylene vinyl alcohol (EVOH), nylon, polyvinyl acetate (PVA), polyacrylonitrile, polypropylene, polystyrene, polyethylene, and the like. Further, the barrier layer 30 may include additives such as lamellar fillers dispersed therein or may comprise a crystalline or semi-crystalline PVOH that is partially or fully hydrolyzed, or combinations of a crystalline, semi-crystalline, and amorphous PVOH.

### Interior Layer

As will be understood, material 80 packaged in containers comprising the multi-layer constructions 1A, 1B, and 1C will often include water. Accordingly, several embodiments include the interior layer 10 to contain the material 80 in the interior 70 of the container, such as for example containers 60A and 60B, and to prevent transmittance of moisture from the interior 70 of the container to the highly amorphous vinyl alcohol barrier layer 30, or to the exterior 100 of the container, such that the highly amorphous vinyl alcohol polymer in the barrier layer 30 will remain dry and under conditions of less than 65% relative humidity no matter what type of material is sealed in the container.

It will be understood however, that the present subject matter does not require the inclusion of the interior layer 10 and that the multi-layer construction can consist of the barrier layer 30 on a substrate, e.g. a protective layer 40 or other filmic or non-filmic substrate as shown in FIG. 1 for example. In this regard, the barrier layer will provide increased barrier properties for the substrate for at least as long as the barrier layer 30 is in a dry state and is subject to conditions of less than 65% relative humidity.

In several aspects, the multi-layer constructions 1A, 1B, and 1C are flexible. The interior layer 10 can therefore comprise a flexible material that does not break, crack, or otherwise substantially lose integrity; but remains sufficiently capable of inhibiting liquid water or water vapor that may be present on a first side 2 of the construction (e.g. in the interior 70 of the containers 60A and 60B) from reaching the highly amorphous vinyl alcohol polymer barrier layer 30 and the second side 3 of the construction (e.g. the exterior 100 of the container 60A and 60B). In this regard, the interior layer 10 acts as a protective layer so that the barrier layer is protected from exposure to moisture present on the first side 2 of the construction.

The interior layer 10 is configured to be substantially water-impermeable in order to maintain the barrier layer 30 in a dry state. Additionally, the interior layer 10 may have a water vapor transmission rate (WVTR) that maintains the barrier layer 30 in a dry state and under conditions of less than 65% relative humidity so that the barrier layer 30 is not undesirably affected by moisture from the interior 70 of the container. In one embodiment the interior layer 10 is impermeable to liquid water and has a WVTR of less than about 80 grams per square meter per 24 hours (i.e. g/m²/24 hr) for a layer thickness of 25.4 microns (1 mil) tested at 37.8° C. (100° F.) and at 90% relative humidity. In another embodiment, the interior layer 10 has a WVTR of less than about 25 g/m²/24 hr at the same film thickness, temperature, and relative humidity.

The interior layer 10 may be situated closer to the first side 2 of the constructions 1A, 1B, and 1C (e.g. the interior 70 of the container) than either of the adhesive layer 20 or the barrier layer 30. In one aspect, the interior layer 10 is in intimate contact with the adhesive layer 20 as shown in the figures.

In various embodiments where other layers are included in the multi-layer constructions 1A, 1B, and 1C, it is important that the interior layer 10 lie on a side of the barrier layer 30 that is closer to the first side 2 of the constructions 1A, 1B, and 1C than is the barrier layer 30. In this way, the interior layer 10 can protect the barrier layer 30 from being exposed to water or humidity due to water content of material that is sealed in the interior 70 of the container, for example. Accordingly, this configuration enables the barrier layer 30, comprising highly amorphous vinyl alcohol polymer, to retain its gas barrier functioning independent from the water contents in the container. In one aspect, the interior layer 10 is situated closer to the interior 70 than other layers of the multi-layer construction. In another aspect, the interior layer 10 defines the first side 2 of the multi-layer construction and the interior surface 61 of the container, such as containers 60A and 60B.

If the multi-layer construction did not include the water-impermeable interior layer 10, liquid contents or humidity from the interior 70 of the container may eventually permeate over time to the barrier layer 30 and as such, could undesirably impair the barrier functioning of the highly amorphous vinyl alcohol polymer in the barrier layer 30 and render the barrier layer inadequate for limiting the amount of air transmitted through the construction or for reducing the amount of air located in the interior 70 of the container. Exposure to liquid water or water vapor may prevent the highly amorphous vinyl alcohol polymer from adequately preventing gas from being transported from the exterior 100 of the container to the interior 70 of the container. If additional HSG were introduced to the interior 70 of the container through transmission of gas from the exterior 100 to the interior 70 of the container, then air-sensitive material 80 therein may degrade and become unsuitable for its intended purpose. In embodiments where the interior layer 10 is not included, as in FIG. 1 for example, the construction 1A can be used in situations wherein moisture is not present on the first side 2 of the construction to such an extent as to undesirably diminish the barrier properties of the barrier layer 30. This may include situations where there is no moisture or very little moisture on the first side 2 of the construction 1A, or in situations where moisture is present but where the barrier properties of the barrier layer 30 are not required for an extended period of time.

The interior layer 10 can comprise any material that is capable of preventing liquid water and excessive amounts of water vapor that may originate from the interior 70 of the container, from coming into contact with the barrier layer 30. In one aspect, the interior layer 10 comprises a polymeric component that is formed into a continuous film, is water-impermeable, and has a sufficiently low WVTR so as to effectively maintain the barrier properties of the highly amorphous vinyl alcohol polymer in the barrier layer 30.

In another embodiment, the interior layer 10 may also act as a sealant layer so that the multi-layer construction, such as 1A, 1B, and 1C, can form the entirety of the container, wherein the interior layer 10 can be sealed to itself such as through application of heat or other type of radiation. Alternatively, the interior layer 10 can be sealed to itself or to another layer of the multi-layer construction, by using heat, an adhesive, or other sealing mechanism. In either event, the seal 50 formed will restrict the contents of the interior 70 of the package from being released to the exterior 100 of the container.

The interior layer 10 may comprise a polymer including one or more of polyethylene, such as low density polyethylene (LDPE), linear low density polyethylene (LLDPE), metallocene linear low density polyethylene (mLLDPE), ultra-low density polyethylene (ULDPE), medium density polyethylene (MDPE), ultra-high weight molecular weight polyethylene (UHWMPE), high density polyethylene (HDPE), polypropylene, polyurethane, polyolefins (linear or branched), halogenated polyolefins, polyamides, polystyrenes, nylon, polyesters including polyethylene terephthalate (PET), polyester copolymers, polyurethanes, polysulfones, styrene-maleic anhydride copolymers, styrene-acrylonitrile copolymers, polyether-amide block copolymers, polyether-ester block copolymers, ionomers based on sodium or zinc salts of ethylene methacrylic acid, polymethyl methacrylates, cellulosics, acrylic polymers and copolymers, polycarbonates, polyacrylonitriles, polybutylene, ionomers, and ethylene-vinyl acetate copolymers. Included in this group are the acrylates such as ethylene methacrylic acid, ethylene methyl acrylate, ethylene acrylic acid and ethylene ethyl acrylate. Also included in this group are polymers and copolymers of olefin monomers having, for example, 2 to about 12 carbon atoms, and in one embodiment, 2 to about 8 carbon atoms. These include the polymer of a-olefins having from 2 to about 4 carbon atoms per molecule. These include polyethylene, polypropylene, poly-1-butene, etc. Films prepared from blends of copolymers or blends of copolymers with homopolymers are also useful.

The thickness of the interior layer 10 is not particularly limited so long as the interior layer 10 offers sufficient water impermeability and minimal water vapor transmission rates to protect the barrier layer 30. The average thickness of the interior layer 10 and can range from about 10 microns (μm) to about 1000 μm. In one embodiment, the interior layer 10 has an average thickness of from about 15 to about 100 μm or more, in one embodiment from about 20 to about 80 μm and in another embodiment, from about 40 to about 60 μm, and particularly about 50 p.m.

In one embodiment, the interior layer 10 comprises a substantially continuous polymeric film comprising a mixture of metallocene linear low density polyethylene (mLLDPE) and ultra low density polyethylene (ULDPE) at a thickness of about 50 μm. Polyethylene resins, and specifically metallocene polyethylene resins, are flexible to resist stress cracking, yet impact and puncture resistant, and offer heat sealing capabilities so that the interior layer 10 can serve as a sealant layer. In one embodiment, suitable polymeric films are also halogen-free and avoid the use of polyvinylidene chloride (PVDC). In one embodiment, the interior layer 10 is transparent and conformable. In another embodiment, the interior layer 10 is also elastomeric. The polymeric films used in the interior layer 10 can be produced by blown or cast extrusion.

### Adhesive Layer

In several embodiments, one or more adhesive layers are included in the barrier construction, shown for example as constructions 1B and 1C. When included, an adhesive layer 20 can be used as a tie layer between the barrier layer 30 and the interior layer 10, and can be in intimate contact with the barrier layer 30. As previously described, when in intimate contact with the barrier layer 30, the adhesive layer 20 may also act as a catalyst in altering the barrier properties of the highly amorphous vinyl alcohol polymer in the barrier layer 30 so that an amount of gas on one side of the multi-layer construction may be reduced.

It will be understood however, that in one embodiment, the multi-layer construction consists of a barrier layer 30 and a substrate 40, and does not include the adhesive layer as shown for example in FIG. 1A. In this embodiment, the barrier layer 30 offers increased barrier performance for the substrate 40 and may be used where there is little or no concern about flex cracking failure of the barrier layer (e.g. in situations where the barrier layer is not subject to substantial flexure or distortion) or where there is little or no concern about reducing the amount of gas on one side of the multi-layer construction (e.g. in situations where only the reduction in the transmission of gas through the barrier construction is important).

In one aspect, the adhesive layer 20 is in intimate contact with the first face 31 of the barrier layer 30. That is, the adhesive layer 20 is directly disposed on the barrier layer 30, on a side closest to the interior 70 of the container. In other embodiments, more than one adhesive layer may be included, for example in FIG. 3 wherein a second adhesive layer 170 in situated on the second face 32 of the barrier layer 30.

As shown in FIGS. 2-5, the adhesive layer 20 typically lays between the interior layer 10 and the barrier layer 30. In this way, the adhesive layer 20 bonds the interior layer 10 to the barrier layer 30. However, it will be understood that in accordance with the present subject matter, various other layers may be positioned between the adhesive layer 20 and the interior layer 10.

In one embodiment, the adhesive layer 20 may also act as cushioning for the relatively thin barrier layer 30 so that the barrier layer does not experience flex-cracking failure upon flexure or stretching of the barrier constriction 1. Because of the cushioning provided by the adhesive layer 20, the barrier layer 30 can be relatively thin compared to if the adhesive layer 20 were not included.

The average thickness of the adhesive layer can range from about 0.5 μm to about 4.5 μm; or a coating weight of about 4 g/m² to about 30 g/m². Adhesive layer thicknesses and coating weights within this range may provide sufficient cushioning for the barrier layer 30 and allow for flexing of the barrier layer 30 without the barrier layer 30 cracking or otherwise being damaged. Preventing cracking or damaging of the barrier layer 30 may maintain continuity of the barrier layer 30 and may promote more efficient and thorough reduction in the amount of gas 90 in the interior 70 of the container.

In other aspects, the adhesive layer 20 is present at an average thickness of about 2.25 μm to about 3 μm, and particularly at about 2.7 μm; or a coating weight from about 15 g/m² to about 20 g/m², and particularly at about 18 g/m². Conventionally thinner adhesive layers having thicknesses of less than about 0.6 μm, or a coating weight of less than about 4 g/m², may not prevent flex cracking of the barrier layer 30 during bending and folding of the multi-layer construction.

Further, these conventionally lower coating weights and thinner adhesive layers may not form into a continuous layer, but may include apertures or discontinuities through the layer. Having an adhesive layer that is not continuous may inhibit the adhesive layer 20 in the multi-layer construction from adequately activating the barrier layer 30 to decrease an amount of air located in the interior 70 of the container or from adequately cushioning the barrier layer from flex cracking.

Intimate contact between the adhesive layer 20 and the barrier layer 30 provided by the above described coating weight and thicknesses, also promotes various other desirable barrier characteristics for the multi-layer construction. More specifically, the barrier layer 30 may contain surface irregularities that can be damaging to the barrier performance of the barrier layer 30, including the one-way barrier properties of the barrier layer 30. While not being bound to any particular theory, it is believed that the adhesive can fill in these irregularities in the first face 31 of the barrier layer 30, and in the second face 32 when a second adhesive layer 170 is included, and can thereby increase the barrier performance of the barrier layer 30.

In another embodiment, two adhesive layers are included in the multi-layer construction 1C as shown in FIG. 3, wherein the first adhesive layer 20 is disposed directly on the first face 31 of the barrier layer 30 and the second 170 is disposed directly on the second face 32 of the barrier layer 30. In this embodiment, the barrier layer 30 is sandwiched between two adhesive layers 20, 170. In this construction, the two adhesive layers 20, 170 on either side of the barrier layer 30 may provide increased cushioning for the barrier layer 30 to inhibit flex cracking. In this embodiment, the second adhesive layer 170 that is disposed on the second face 32 of the barrier layer 30 may be tailored so as not to affect the one-way barrier properties of the barrier layer 30 so that an amount of air located in the interior 70 of the container may be reduced while at the same time, air from the exterior 100 of the container may be prevented from being introduced into the interior 70 of the container through the multi-layer construction.

The adhesive composition used in the adhesive layers 20, 170 is not particularly limited by the present subject matter, and can include any number or combinations of drying adhesives, contact adhesives, hot-melt adhesives, reactive adhesives, natural or synthetic adhesives, or pressure sensitive adhesives.

In one embodiment, the adhesive used in one or both of the adhesive layers 20, 170 compromises a pressure sensitive adhesive (PSA). The PSA can comprise any combination of solvent adhesives, ultraviolet adhesives, 100% solids adhesives, hot melt adhesives, and emulsion adhesives including emulsion acrylic adhesives, or olefin block copolymer adhesives. Suitable pressure sensitive adhesives can be composed of elastomeric polymers with or without tackifiers. A variety of polymers can be used to manufacture suitable pressure sensitive adhesives; for example, acrylic and methacrylic ester homo- or copolymers, butyl rubber based systems, silicones, nitriles, styrene block copolymers, ethylene-vinyl acetate, urethanes, vinyl esters and amides, olefin copolymer materials, natural or synthetic rubbers, and the like. Other pressure sensitive adhesives can be used; such as those comprising polyurethane polymers, for example.

In one embodiment, the adhesive composition is an aqueous mixture of a pressure sensitive adhesive, wherein the aqueous portion of the adhesive composition may be removed by drying to form the adhesive layer 20.

The aqueous polymer compositions generally constitute from about 40% to about 80% by weight of a polymer with the balance being made up of water and minor amounts of volatile organic compounds and unreacted monomer surfactants, tackifiers, etc. The noted water may be present in an amount of from about 20% to about 60% by weight of the adhesive composition.

The aqueous mixtures of a pressure sensitive adhesive may comprise an acrylic based polymer matrix comprising particles of the acrylic polymer dispersed in an aqueous medium, or a rubber based polymer matrix adhesive.

The aqueous acrylic based polymers in accordance with the present subject matter may comprise homopolymers and copolymers of various acrylic monomers including alkyl acrylates such as ethyl acrylate, butyl acrylate, propyl acrylate, 2-ethylhexyl acrylate, isooctyl acrylate, isodecyl acrylate, etc.; alkyl methacrylates such as methyl methacrylate, ethyl methacrylate, butyl methacrylate, etc. These acrylate monomers may be copolymerized with vinyl-unsaturated monomers such as vinyl acetate, vinyl propionate; styrenic monomers such as styrene, methyl styrene, etc.; unsaturated carboxylic acids such as acrylic acid, methacrylic acid, itaconic acid, maleic acid, fumaric acid, etc.; acrylamide, vinyl caprolactam, etc. The rubber based pressure sensitive adhesive polymer matrices useful in the present subject matter are normally pressure sensitive adhesive matrices based on styrene and butadiene random polymers and mixtures thereof.

In one exemplary embodiment, the adhesive layers 20, 170 of the present subject matter comprise a pressure sensitive adhesive that forms a permanent bond. In one aspect, the adhesive layer 20 bonds together the interior layer 10 and the barrier layer 30; and the second adhesive layer 170 (if included) bonds together the barrier layer 30 and the exterior layer 40. In another embodiment, the adhesive layers 20, 170 can be used to bond the barrier layer 30 to other different layers.

The copolymers for the adhesive of the instant subject matter can be stabilized against UV and oxidative degradation by using UV stabilizers and antioxidants. Fillers, colorants, tackifiers, plasticizers, oils, and the like, may also be added.

### Exterior Layer

In several embodiments, the multi-layer construction includes a water-impermeable exterior layer 40 that may function in many respects similarly to the water-impermeable interior layer 10. In this regard, the exterior layer 40 acts as a protective layer so that the barrier layer 30 is protected from exposure to moisture present at the second side 3 (e.g. the exterior 100) of the multi-layer construction. In the several methods described herein, the exterior layer 40 may also be used as the substrate 40 upon which the solution of highly amorphous vinyl alcohol polymer dissolved in a solvent is applied and dried to form the barrier layer 30. In other embodiments, a different layer may be used as the substrate 40 upon which the barrier layer is formed.

As will be understood, containers such as container 60A and 60B for example comprising the multi-layer construction will often be placed in environments subject to water and under conditions of more than 65% relative humidity. Accordingly, the exterior layer 40 may be used to prevent transmittance of liquid water or water vapor from the exterior 100 of the container to the highly amorphous vinyl alcohol barrier layer 30. In this way, the highly amorphous vinyl alcohol polymer in the barrier layer 30 can remain dry and can be maintained under conditions of less than 65% relative humidity. Accordingly, the highly amorphous vinyl alcohol polymer may provide superior barrier properties regardless of the environment to which the multi-layer construction is exposed.

In one embodiment, the exterior layer 40 is configured to be substantially water-impermeable in order to maintain the barrier layer 30 in a dry state and isolated from water at the exterior 100 of the container. Additionally, the exterior layer 40 may have a water vapor transmission rate that maintains the barrier layer 30 under conditions of less than 65% relative humidity so that the gas barrier properties of the barrier layer 30 are not undesirably affected by moisture from the exterior 100 of the container.

In several embodiments, the exterior layer 40 is situated closer to the exterior 100 of the container than the barrier layer 30. It will be understood that the exterior layer 40 is not required to be in intimate contact with the barrier layer 30, but rather, one or more additional and different layers may be disposed therebetween, such as an adhesive layer 170. In one aspect, the exterior layer 40 is in intimate contact with the barrier layer 30 as shown in FIGS. 1, 2, 4 and 5, wherein the barrier layer 30 is directly disposed on the first face 41 of the exterior layer 40. Accordingly, the water-impermeable exterior layer 40 is disposed closer to the second side 3 of the multi-layer construction than is the barrier layer 30.

In one embodiment, the exterior layer 40 is impermeable to liquid water and has a WVTR of less than about 80 grams per square meter per 24 hours (i.e. g/m²/24 hr) for a layer thickness of 25.4 μm (1 mil) tested at 37.8° C. (100° F.) and at 90% relative humidity. In another embodiment, the exterior layer 40 has a WVTR of less than about 25 g/m²/24 hr at the same film thickness, temperature, and relative humidity.

Because the exterior layer 40 is situated closer to the second side 3 of the barrier construction (e.g. the exterior 100 of the container) than the barrier layer 30, the exterior layer 40 is able to protect the barrier layer 30 from the liquid and/or humidity that may be present at the second side 3 of the barrier construction. As previously described, this protection allows the barrier layer 30, comprising highly amorphous vinyl alcohol polymer, to retain its gas barrier functioning independent from the water in the environment to which the container is exposed. Accordingly, the container may be placed in water-containing environments without substantially affecting the barrier properties of the highly amorphous vinyl alcohol polymer in the barrier layer 30.

If the multi-layer construction did not include the water-impermeable exterior layer 40, the highly amorphous vinyl alcohol polymer in the barrier layer 30 may not adequately reduce the amount of air located in the interior 70 of the container after being exposed to conditions over 65% relative humidity for an extended period of time. A multi-layer construction not including an exterior layer 40 eventually allows moisture from the environment to reach the barrier layer 30, thereby reducing the barrier properties of the barrier layer 30, and allowing the amount of gas 90 in the interior 70 of the container to increase, rather than decrease. This is because exposure to liquid water or water vapor from the environment may impair the gas barrier properties of the highly amorphous vinyl alcohol polymer in the barrier layer 30, and the highly amorphous vinyl alcohol polymer may not adequately prevent gas from being transported through the barrier layer 30 from the exterior 100 of the container to the interior 70 of the container.

The exterior layer 40 can comprise any material that is capable of preventing liquid water and excessive amounts of water vapor that may originate from the exterior 100 of the container from coming into contact with the barrier layer 30. In one aspect, the exterior layer 40 comprises a polymeric component that is formed into a continuous film, is water-impermeable, and has a sufficiently low WVTR so as to effectively maintain the barrier properties of the highly amorphous vinyl alcohol polymer in the barrier layer 30 by maintaining the barrier layer 30 in a dry state and under conditions of less than 65% relative humidity.

The exterior layer 40 has a thickness that is not particularly limited by the present subject matter so long as the exterior layer 40 offers sufficient water impermeability and minimal water vapor transmission rates to protect the barrier properties of the barrier layer 30. In this respect, the exterior layer 40 can comprise a water-impermeable layer having a thickness ranging from about 10 μm to about 1000 μm. In one aspect, the thickness of the exterior layer 40 ranges from about 15 μm to 100 μm, from about 20 to 80 μm, and in one embodiment has a thickness of about 36 μm.

The exterior layer 40 may comprise any of the polymers, or combinations thereof, as listed above as being suitable for the interior layer 10. Suitable films used for the exterior layer 40 are halogen-free and avoid the use of polyvinylidene chloride (PVDC). In one embodiment, the exterior layer 40 comprises an uncoated polyethylene terephthalate film that is bi-axially oriented.

### Optional Layers, Additives and Treatments

The barrier constructions of the present subject matter can include other layers, additives within or separate from the described layers, or treatments and can include printing, printing receptive layers or treatments, hydrophobic layers or treatments, additional laminated film layers, or the like. Examples include priming, printing, hydrophobic treatments, etc. Additives, including air and/or oxygen scavengers, slip and antiblock agents, antifogs, antistatics, and processing aids can also be used. The described layers can be coextruded, blended, or laminated with other layers including metal foils, other polymers films, fillers, adhesive/tie layers, or the like.

### Combinations of Articles

In accordance with the present subject matter, one embodiment depicted in FIG. 4 includes a combination 130A of a material 80 that is packaged inside a sealed container 60A comprising the halogen-free multi-layer construction. In one embodiment, the combination 130A comprises an air-sensitive material 80. The container can be entirely defined by the multi-layer construction, such as that depicted in FIG. 4; or can be partially defined by the multi-layer construction, such as the container 60B depicted in FIG. 5, wherein the material 80 is sealed within the interior 70 of the container 60B.

The material 80 is not particularly limited by the present subject matter, and can include any material intended for human consumption or sustenance, or any other type of material that may or may not be sensitive to degradation upon exposure to air. For example, the material 80 can include an electronic component that may suffer degradation upon exposure to various components of air.

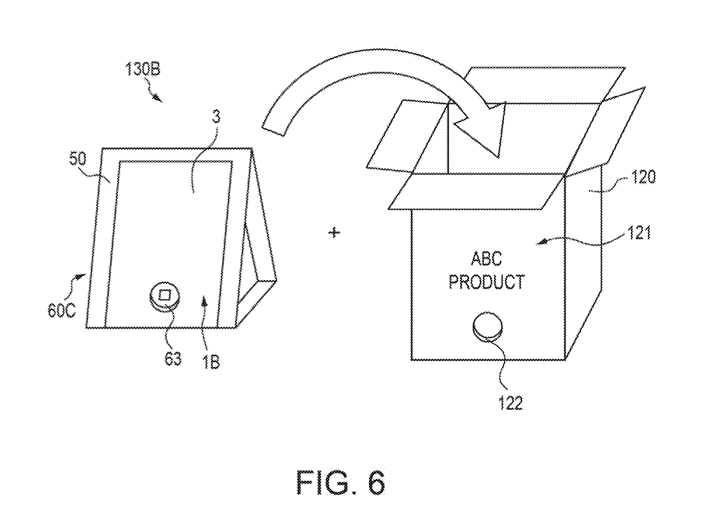

The combination can further include packaging disposed at an exterior of the container. Such packaging can be used for advertising or communication purposes, for protection of the container and the material 80, or for other purposes. This aspect and combination 130B are depicted for example in FIG. 6, showing packaging 120 and the multi-layer construction 1B bonded to itself with a seal 50 to thereby define a container 60C having a material sealed therein, such that the second side 3 of the multi-layer construction is facing outward.

The container 60C shown in FIG. 6 includes a dispensing means 63 used to access the interior of the container 60C and thereby dispense the material sealed in the container 60C without having to permanently rupture the container 60C. Dispensing means 63 can include a spout, a valve, or other structure that can be selectively opened or closed in order to access the material sealed in the interior 70 of the container 60C. As shown in FIG. 6, the container 60C, and the material sealed therein, are placed (arrow) inside a box-type package 120 having indicia 121 printed thereon and having an opening 122 through which the dispensing means 63 may be accessible from the exterior of the box-type package 120.

One example of this type of combination 130B can be a bag-in-box wine product or other bag-in-box liquid-containing material, wherein the liquid material is sealed inside a flexible bag and placed inside a box for distribution and/or sale. In this aspect, the entire container 60C is defined by the multi-layer construction, save for the dispensing means 63. By including the multi-layer construction as part of the container, an amount of air that may be sealed or trapped in the interior 70 of the container can be reduced in order to maintain the palatability of the air-sensitive material 80 therein.

In accordance with the present subject matter, other various combinations, including the multi-layer construction, are contemplated. For example, a combination, in accordance with the present subject matter, may include a material sealed in a container, such as that depicted in FIG. 5 or other type of container including the multi-layer construction, with or without packaging.

### Methods

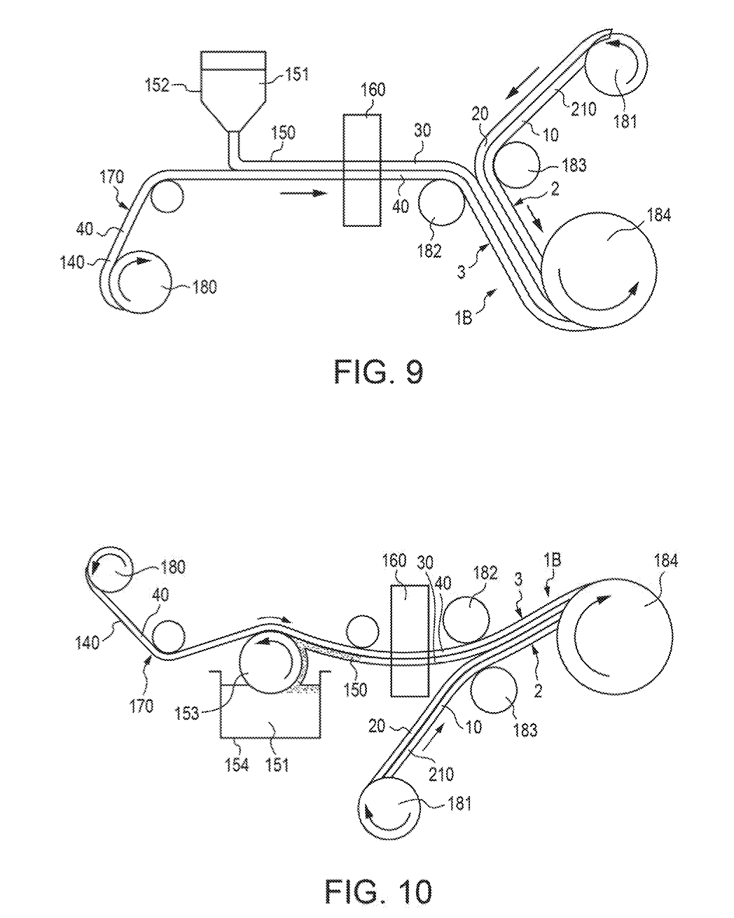

In accordance with the present subject matter, various methods of making a barrier layer 30 and the multi-layer construction are provided. The methods incorporate the description of the various layers of the barrier construction as described herein. The methods can be used to form a continuous or substantially continuous barrier layer as part of a barrier construction. The methods will be described in conjunction with the figures, including FIGS. 9 and 10.

FIG. 9 depicts a continuous or semi-continuous process for forming a barrier layer 30, wherein a solution 151 is applied to a substrate 140 using a curtain coating technique. FIG. 10 depicts a continuous or semi-continuous process for forming a barrier layer 30, wherein a solution 151 is applied to a substrate 140 using a reverse gravure coating technique. Both FIGS. 9 and 10 show a filmic substrate 140 wound on a roll 180. The filmic substrate 140 may optionally have an adhesive layer 170 on a face of the substrate 140. The substrate is unwound in the direction of the arrows and the solution 151 is coated on the substrate to form a coating layer 150 on the substrate 140. The coating layer 150 is applied by curtain coating in FIG. 9, wherein the solution 151 is dispensed as a curtain from a holding tank 152 to cover the substrate 140. The coating layer 150 is applied by reverse gravure coating in FIG. 10, wherein the solution 151 is dispensed from a holding tank 154 to cover the substrate 140 using a reverse gravure roller 153. The coating layer 150, substrate 140, and optional adhesive layer 170 are then run through a drying station 160 to substantially remove the solvent from the coating layer 150 to thereby form the barrier layer 30 of highly amorphous vinyl alcohol polymer on the substrate 140. A substrate 210, which can be a protective layer 10 or a release liner for example, and an adhesive layer 20 is unwound from roller 181 and laminated between lamination rollers 182, 183 to the barrier layer 30 and the substrate 140 to form the multi-layered construction 1B for example. Alternatively, the adhesive layer 20 may be applied directly to the barrier layer 30 for example by coating the barrier layer 30 with an adhesive composition. Thereafter, the substrate 210 can be laminated to the adhesive layer 20. The multi-layered construction can then be rolled onto roller 184.

In one embodiment, a method of forming a layer of highly amorphous vinyl alcohol polymer on a substrate is provided. The layer of highly amorphous vinyl alcohol polymer can define a barrier layer 30 as described herein and the filmic substrate 140 can define a release liner, a water impermeable protective layer 40, or other substrate, for example a layer of the multi-layer construction as described herein. The method includes dissolving highly amorphous vinyl alcohol polymer in solvent to form a solution 151 and applying the solution 151 to a substrate 140 to form a coating layer 150 thereon. The highly amorphous vinyl alcohol polymer can be a polymer as described herein, and may have an average level of crystallinity of less than about 35%, less than about 25%, or less than about 20% and a degree of saponification of the highly amorphous vinyl alcohol copolymer can be from about 50 mol % to about 98 mol %.

The highly amorphous vinyl alcohol polymer may be included in almost any amount in the solution 151, as the long as the coating layer 150 can form a substantially continuous barrier layer 30 upon drying.

The highly amorphous vinyl alcohol polymer may be dissolved in the solvent by adding the highly amorphous vinyl alcohol polymer to the solvent when the solvent is at room temperature (i.e. approximately 20-25° C.) or at an elevated or reduced temperature. The highly amorphous vinyl alcohol polymer may be dissolved using procedures including stirring or otherwise agitating the solvent and highly amorphous vinyl alcohol polymer, and heating the components to about 80-90° C. for example. Dissolving the highly amorphous vinyl alcohol polymer in the solvent produces a solution 151.

The solvent can include any solvent capable of dissolving the highly amorphous vinyl alcohol polymer to form a solution. In one embodiment, the solvent includes water.

The solution 151 may further include ethanol and/or other alcohol that is miscible in the solvent, optional additive(s), or a combination thereof.

The amount of highly amorphous vinyl alcohol polymer may be about 0.1 wt % to about 90 wt %, from about 0.1 wt % to about 35 wt %, from about 5 wt % to about 35 wt %, or from about 5 wt % to about 15 wt % of the total weight of the solution, with the balance comprising a solvent such as water, an alcohol miscible in the solvent, optional additive(s), or a combination thereof if included.

In one embodiment, the amount of miscible alcohol, optional additive(s), or a combination thereof that is included in the solution ranges from about 0-50 wt % of the weight of the solvent. The miscible alcohol, optional additive(s), or a combination thereof can be added to the solvent before addition of the highly amorphous vinyl alcohol polymer, or can be added after the highly amorphous vinyl alcohol polymer is dissolved in the solvent.

The methods also include applying the solution to the substrate 140 to form a coating layer 150. The substrate 140 is not particularly limited and can include any of a variety of filmic substrates as described herein. In one embodiment, the substrate 140 is one of an interior 10 or exterior 40 water impermeable protective layers as described herein that provides protection to the barrier layer 30 from exposure to moisture present on one side of the barrier construction.

The method used to apply the solution 151 to the substrate 140 is not particularly limited, and may include one or more of gravure coating, reverse gravure coating (FIG. 10), offset gravure coating, curtain coating (FIG. 9), roll coating, brush coating, knife-over roll coating, metering rod coating, reverse roll coating, doctor knife coating, dip coating, die coating, spray coating, printing, electrostatic coating, flow coating, spin coating, and combinations thereof.

The various methods include applying the solution 151 at a wet thickness such that upon drying, the formed barrier layer 30 has a dry thickness of about of about 0.1-5 g/m². In one embodiment, and depending upon the wt % of highly amorphous vinyl alcohol polymer in the solution, the solution 151 may be applied at a wet thickness of about 0.1-100 g/m². Upon drying of the coating layer 150, the solvent is removed leaving a barrier layer 30 of highly amorphous vinyl alcohol polymer. It will be understood that in order to obtain a barrier layer 30 having a dry thickness of about 0.1-5 g/m², that the wet thickness of the coating layer 150 applied to the substrate 140 can be decreased as the wt % of highly amorphous vinyl alcohol polymer in the solution 151 is increased.

In one embodiment, the solution 151 is applied by either curtain coating (FIG. 9) or reverse gravure coating (FIG. 10). In one aspect, the solution 151 is applied in a continuous or semi-continuous process on conventional converting equipment to a filmic substrate 140 as shown for example in FIGS. 9-10. These coating methods are able to produce a thin continuous coating layer 150 of solution 151, and therefore upon drying produces a relatively thin (e.g. about 1 μm thick) continuous barrier layer 30 that has tight gauge consistency and good visual clarity through the barrier layer 30 compared to other coating methods and materials. Further, these coating operations do not require specialized vapor deposition equipment and do not require the addition of fillers such as clay platelets as added barrier reinforcement, thereby saving cost and time expenditures.

The methods further include substantially removing solvent from the solution 151 that has been applied to the substrate 140 in order to produce a dry or substantially dry layer of highly amorphous vinyl alcohol polymer on the substrate 140 that can act as a barrier layer 30. The operation of removing the solvent from the coating layer 150 is not particularly limited and can include any process that results in a barrier layer 30 of dry or substantially dry highly amorphous vinyl alcohol polymer on the substrate 140. In this respect, this operation is also referred to herein as a “drying” operation and can be performed at a drying station 160 in a continuous or semi-continuous process depicted in FIGS. 9-10 for example. The drying operation can include natural/ambient air drying, vacuum drying, forced air drying, drying using heat or other energy type, dielectric drying, freeze drying, supercritical drying, distillation, reduced-pressure evaporation, or other methods and combinations thereof, such that the solvent substantially evaporates or is otherwise substantially removed from the coating layer 150. In one aspect, the solvent is removed from the coating layer 150 by forcing heated air over the coating layer 150 of solution 151. After drying, the barrier layer can be covered with a release liner or other layer such as a water-impermeable protective layer.

In one embodiment, a method of improving gas barrier properties of a film is provided. The method includes providing a solution 151 of highly amorphous vinyl alcohol polymer dissolved in a solvent as described herein. The method includes applying the solution on a film 140 to thereby form a coating layer 150 on the film 140. The method includes evaporating the solvent from the coating layer 150 to form a barrier coating 30 of dried highly amorphous vinyl alcohol polymer on the film 140. In one aspect, the barrier coating 30 has a dry coating weight of about 0.01-85 g/m².

The method may further include restricting liquid water and water vapor from reaching the barrier layer 30 such that the barrier layer 30 remains dry and is not subjected to conditions of more than 65% relative humidity. Such operation can be accomplished for example by using a water impermeable protective layer 10, 40 on one or both sides of the barrier layer 30, wherein the protective layers 10, 40 have a WVTR of less than about 80 grams per square meter per 24 hours (i.e. g/m²/24 hr) for a layer thickness of 25.4 microns (1 mil) tested at 37.8° C. (100° F.) and at 90% relative humidity. The protective layer(s) is thus able to maintain the barrier layer 30 in a dry state and under conditions of less than 65% relative humidity. As such, the barrier layer 30 is not undesirably affected by moisture from the first 2 or second side 3 of the multi-layer construction. In this aspect, the protective layer 40 may be used as the filmic substrate 140.

In several embodiments, the method further includes depositing an adhesive to the barrier layer 30 on a side 32 of the barrier layer 30 opposite from the filmic substrate 140. The adhesive layer 20 can include one or more adhesives as described herein. In one embodiment, the adhesive layer 20 is applied at a coating weight of about 4-30 g/m² and includes a PSA. The adhesive layer 20 can be applied directly to the dry barrier layer 20, to the wet coating layer 150 of solution 151, or can be provided on a backing material 210, for example barrier layer 10, and laminated to the dry barrier layer 30 as shown in FIGS. 9-10.

The methods may also include positioning a second adhesive layer 170 between the coating layer 150 and the filmic substrate 140. Although the second adhesive layer 170 is not depicted in FIGS. 9-10 as being separate and distinct from the filmic substrate 140, it will be appreciated that the second adhesive layer 170 can be a separate and distinct layer from the other layers of the multi-layer construction. In this regard, the second adhesive layer 170 can be provided on the filmic substrate 140 before the barrier layer 30 is formed thereon, such that the barrier layer 30 directly abuts the second adhesive layer 170 and the second adhesive layer 170 is positioned between the filmic substrate 140 and the barrier layer 30.

In several embodiments, the methods also include applying a second substrate layer 210, such as a polymer film for example, to the adhesive layer 20 on a side 21 of the adhesive layer 20 opposite from the barrier coating 30. The second substrate layer 210 may be moisture-impermeable protective layer 10 as described herein in order to help protect the barrier layer 30 from coming into contact with moisture.

A method of making a gas barrier construction is also provided. The gas barrier construction is configured to limit the amount of gas transmitted through the construction from a second side 3 of the gas barrier construction to a first side 2 of the gas barrier construction. The method includes providing a first moisture impermeable film layer 140, 40 having a first face 41 and an oppositely directed second face 42. The method includes applying a solution 151 comprising highly amorphous vinyl alcohol polymer dissolved in a solvent to the first face 41 of the first moisture impermeable film to thereby form a coating layer 150. The coating layer 150 is dried by substantially removing the solvent from the coating layer 150 to thereby form a barrier layer 30. An adhesive layer 20 is disposed on a side 31 of the barrier layer 30 opposite from the first moisture impermeable film layer 140, 40. A second moisture impermeable film layer 210, 10 is positioned on a side 21 of the adhesive layer 20 opposite from the barrier layer thereby forming the gas barrier construction. The second face 42 of the first moisture impermeable film layer 40 is directed toward the second side 3 of the gas barrier construction. The second moisture impermeable film layer 210, 10 includes a face 11 that is oppositely directed from the adhesive layer 20 and is directed toward the first side 2 of the gas barrier construction.

In one aspect, the second face 42 of the first moisture impermeable film layer 40 defines the second side 3 of the gas barrier construction. In another aspect, the face 11 of the second moisture impermeable film layer 10 that is oppositely directed from the adhesive layer 20 defines the first side 2 of the gas barrier construction. Further, the adhesive layer 20 may be disposed directly to the barrier layer 30 and the barrier layer is not subject to conditions of more than 65% relative humidity.

A method of making a multi-layer construction defining a first side 2 and an oppositely directed second side 3 is provided, wherein the multi-layer construction is configured to reduce an amount of gas 90 on the first side 2 of the multi-layer construction. The method includes providing a water-impermeable protective layer 10 and includes disposing an adhesive layer 20 on the side of the water-impermeable protective layer 10 that is nearest the second side 3 of the multi-layer construction. When incorporated as part of a container as shown in FIGS. 4-5, the first side 2 of the multi-layer construction may face the interior 70 of the container and the protective layer 10 may define an interior layer of the multi-layer construction.

The method also includes depositing a barrier layer 30 on a side of the adhesive layer 20 that is opposite from the water-impermeable protective layer 10, such that the adhesive layer 20 and the barrier layer 30 directly abut and are in intimate contact with each other. The deposition of the barrier layer 30 on the adhesive layer can be accomplished as previously described by dissolving a highly amorphous vinyl alcohol polymer in a solvent, applying the solution to the adhesive layer, and drying the solution to form the barrier layer 30. In one aspect, the method also includes arranging a water-impermeable protective layer 40 on a side of the barrier layer 30 that is opposite from the adhesive layer 20, such that the water-impermeable protective layer 40 is closer to the second side 3 of the multi-layer construction than the barrier layer 30. The water-impermeable protective layer 40 may or may not directly abut the barrier layer 30.

In one aspect, wherein an exterior layer 40 is included in the multi-layer construction, the method may include adding together a highly amorphous vinyl alcohol polymer, optional additive(s), and water to form a barrier composition 151, wherein the highly amorphous vinyl alcohol polymer is dissolved in the water. The barrier composition 151 can be applied to the first face 41 of exterior layer 40 and dried thereon. Drying substantially removes the water component in the barrier composition 151 and thereby forms the barrier layer 30, comprising highly amorphous vinyl alcohol polymer, in dry form. The method includes applying the barrier composition 151 of highly amorphous vinyl alcohol polymer, optional additive(s), and water in an amount, such that upon drying of the barrier composition 151, the dry barrier layer 30 has a thickness of about 0.015 μm to about 12 μm, and particularly about 0.18 μm; or a dry coating weight from about 0.1 g/m² to about 85 g/m², and particularly about 1.2 g/m². Other methods of forming the barrier layer 30 can be used. In one embodiment, the exterior layer 40 comprises an uncoated PET film or an uncoated bi-axially oriented PET film. In another embodiment, a highly amorphous vinyl alcohol polymer is extruded by casting or blown into a film to form the barrier layer 30.

Once the barrier layer 30 is formed, the method may include depositing the adhesive layer directly on the first face 31 of the barrier layer 30. In one aspect, an adhesive composition is applied directly to the barrier layer 30. The adhesive composition can comprise for example, a solvent adhesive or an emulsion acrylic adhesive that contains a liquid vehicle. The adhesive composition can be dried to thereby remove the liquid vehicle from the adhesive composition and to thereby form the adhesive layer 20 directly on the first face 31 of the barrier layer 30. In this aspect, the interior protective layer 10 may then be disposed directly along the adhesive layer 20 in order to make the multi-layer construction. In another aspect, the adhesive composition can first be applied to the interior layer 10 and dried thereon in order to form the adhesive layer 20. Thereafter, the adhesive layer 20 on the interior layer 10 can be applied to the first face 31 of the barrier layer 30 on the exterior layer 40 to thereby make the multi-layer construction.

When the multi-layer construction is formed, the barrier layer 30 contains a highly amorphous vinyl alcohol polymer that is dry and which may be in intimate contact with the adhesive layer 20, which is disposed closer to the first side 2 of the multi-layer construction than the barrier layer 30. Intimate contact between the first face 31 of the barrier layer 30 and the adhesive layer 20 thereby promotes the one-way barrier properties of the highly amorphous vinyl alcohol polymer in the barrier layer 20.

When the multi-layer construction is fully assembled, the highly amorphous vinyl alcohol polymer in the barrier layer 30 may be maintained in conditions of less than 65% relative humidity.

In accordance with the present subject matter, a method of reducing an amount of gas 90 in a container is provided. The container can include a wall that defines the container and separates an interior 70 of the container from an exterior 100 of the container. The wall can include the multi-layer construction 1B as depicted in FIG. 2. In this regard, the multi-layer construction is arranged such that the wall separating the interior 70 from the exterior 100 of the container is at least partially defined by the multi-layer construction 1B. In one aspect, the multi-layer construction defines the entire wall, such as that depicted in FIG. 4 for example. In FIG. 4 the multi-layer construction 1B comprises the entire container 60A. In another aspect, the multi-layer construction defines a portion of the wall, such as that depicted in FIG. 5 for example, wherein the multi-layer construction covers an opening in the tray 110. In FIG. 5 the multi-layer construction comprises a portion of the container 60B.

The method includes providing a multi-layer construction including a highly amorphous vinyl alcohol polymer barrier layer 30 and an adhesive layer 20. The adhesive layer 20 is disposed on a side of the highly amorphous vinyl alcohol polymer barrier layer 30 that is closest to the interior 70 of the container and directly abuts the highly amorphous vinyl alcohol polymer barrier layer 30. The method includes arranging the multi-layer construction, such that the construction defines at least a portion of the wall separating the interior 70 from the exterior 100 of the container. The method includes keeping the highly amorphous vinyl alcohol polymer barrier layer 30 dry and under conditions less than about 65% relative humidity. In this regard, and in order to maintain these conditions, the multi-layer construction can optionally include and interior layer 10 and/or an exterior layer 40. The highly amorphous vinyl alcohol polymer of the barrier layer 30 can include Nichigo G-polymer. Other additional operations can be incorporated into the exemplary methods, such as including an air-sensitive material 80 in the interior 70 of the container for example.

### EXAMPLES

The functioning of the multi-layer construction in accordance with the present subject matter is further demonstrated in the following Examples 1-2 and 4 involving multi-layer structures including a highly amorphous vinyl alcohol polymer (HAVOH) as compared with Comparative Example 3. The following Table 4 indicates the construction of various barrier structures.

TABLE 4
Multi-layer Barrier Structures in Examples 1-4

| | | | Comparative | |
|---|---|---|---|---|
| Layer | Example 1 | Example 2 | Example 3 | Example 4 |
| Interior Layer | mLLDPE/LLDPE | mLLDPE/LLDPE (50 μm) | EVA/LDPE/mLLPDE | EVA (81 μm) |
| | (50 μm) | | | |
| Adhesive Layer | Solvent | Solvent Adhesive (18 g/m²) | PP/PE Elastomer | Emulsion Acrylic |
| | Adhesive | | | Adhesive |
| | (18 g/m²) | | | (18 g/m²) |
| Barrier Layer | HAVOH (1.2 g/m²) | HAVOH (1.2 g/m²) | EVA GMAH/COC | HAVOH |
| | | | | (1.2 g/m²) |
| Second | none | none | none | Emulsion Acrylic |
| Adhesive Layer | | | | Adhesive |
| | | | | (18 g/m²) |
| Exterior Layer | PET (36 μm) | None | EVOH/Surlyn | EVA (81 μm) |

In the above Table 4, Example 1, Example 2, and Example 4 are multi-layer barrier constructions in accordance with the present subject matter including a barrier layer comprising HAVOH in intimate contact with an adhesive layer, while Example 3 is a conventional multi-layer barrier construction not including HAVOH.

The above Examples 1-4 were evaluated by sealing the multi-layer construction to itself in order to form a container similar to that depicted in FIG. 4. In each example, water and an amount of HSG (which included various components of air comprising oxygen gas, nitrogen gas, hydrogen gas, etc.) were sealed in the container using a heat seal.

The following Table 5 indicates performance characteristics in reducing the amount of HSG sealed in each container over time for the above barrier structures of Examples 1-4. The data in Table 5 represents the diameter (D) of the HSG air bubble as represented in FIG. 4 that was sealed in the interior of the container.

TABLE 5
Performance Characteristics of Examples 1-4

| | | | Comparative | |
|---|---|---|---|---|
| Elapsed Time | Example 1 | Example 2 | Example 3 | Example 4 |
| Start | 20 mm | 20 mm | 16 mm (less than | 30 mm |
| | | | about 5% of the | |
| | | | volume of the | |
| | | | interior) | |
| 29 days | 12 mm | 14 mm | | |
| 108 days | | | | 30 mm |
| 118 days | 2 mm | 27 mm | | |
| 128 days | 0 mm | | | |
| 1169 days | | | Increased in size | |
| | | | to about 80-90% | |
| | | | of the volume of | |
| | | | the interior | |

As can be seen, the container formed from the multi-layer construction of Example 1 was able to continually reduce the amount of HSG sealed in the container up until at least day 128 until the amount of HSG was decreased to approximately zero. Since air is only about 20% oxygen, there appears to be a removal of all gas types sealed within the container. The container formed from the multi-layer construction of Example 2 was able to initially reduce the amount of HSG sealed in the container, but thereafter the amount of HSG increased between day 29 and day 118. While not being bound to any particular theory, it is believed that the HAVOH barrier layer in Example 2 was exposed to environmental humidity due to there being no exterior layer provided in the multi-layer construction. It is believed that exposure to moisture compromised the barrier properties of the HAVOH barrier layer and thereby allowed the amount of HSG in the container to increase between day 29 and day 118. Although the container formed from the multi-layer construction of Example 4 did not reduce the amount of HSG sealed in the container by day 108, the amount of HSG also did not increase. In contrast to Examples 1-2 and 4, the container formed from the multi-layer construction of Comparative Example 3 increased significantly by day 1169, such that a majority (80%-90%) of the volume of the interior of the container was occupied with gas, rather than with water.

Further detailed analysis was conducted on Examples 1, 2, and 4. The following Table 6 indicates the construction of Examples 1, 2, and 4 and more comprehensive performance characteristics in reducing the amount of HSG sealed in each container over time.

TABLE 6
Multi-Layered Barrier Structures and Performance Characteristics in Examples 1, 2, 4

| Layer | Example 1 | | | Example 2 | | | Example 4 | | |
|---|---|---|---|---|---|---|---|---|---|
| Interior | LLDPE/mPE Film (50 μm) | | | LLDPE/mPE Film (50 μm) | | | EVA Film (18% VA) (81 μm) | | |
| Adhesive 1 | Emulsion Acrylic adhesive | | | Emulsion Acrylic adhesive | | | Hot Melt adhesive (18 gsm) | | |
| | (18 gsm) | | | (18 gsm) | | | | | |
| Barrier | HAVOH (1.2 gsm) | | | HAVOH (1.2 gsm) | | | HAVOH (1.2 gsm) | | |
| Adhesive 2 | None | | | None | | | Hot Melt adhesive (18 gsm) | | |
| Exterior | BOPET (36 μm) | | | None | | | EVA Film (18% VA) (81 μm) | | |
| Reading | Day | Diameter | Area Δ | Day | Diameter | Area Δ | Day | Diameter | Area Δ |
| 1 | 0 | 20.0 mm | 0.0% | 0 | 20.0 mm | 0% | 0 | 25.7 mm | 0.0% |
| 2 | 29 | 12.0 mm | −64.0% | 29 | 14.0 mm | −51% | 68 | 25.7 mm | 0.0% |
| 3 | 88 | 8.0 mm | −84.0% | 88 | 20.0 mm | 0% | 101 | 25.7 mm | 0.0% |
| 4 | 121 | 2.0 mm | −99.0% | 121 | 27.0 mm | 82% | 131 | 27.3 mm | 12.8% |
| 5 | 127 | 0.0 | −100% | 151 | 34.0 mm | 189% | 161 | 25.0 mm | −5.4% |
| 6 | 151 | 0.0 | −100% | 181 | 39.5 mm | 290% | 199 | 23.3 mm | −18% |
| 7 | 181 | 0.0 | −100% | 219 | 48.3 mm | 484% | 220 | 19.0 mm | −45% |
| 8 | 219 | 0.0 | −100% | 240 | 54.0 mm | 629% | 255 | 6.0 mm | −95% |
| 9 | 275 | 0.0 | −100% | 275 | 59.3 mm | 779% | | | |

As can be seen, the container formed from the multi-layer construction of Example 1 was able to continually reduce the amount of HSG sealed in the container up until at least day 127, wherein the amount of HSG was decreased to a diameter of approximately zero and maintained there up to at least day 275. The container formed from the multi-layer construction of Example 2 was able to initially reduce the amount of HSG sealed in the container up to at least day 29, but thereafter the amount of HSG increased between day 29 and day 275. While not being bound to any particular theory, it is believe that the HAVOH barrier layer in Example 2 was exposed to environmental humidity due to there being no exterior layer provided in the multi-layer construction. It is believed that exposure to moisture compromised the barrier properties of the HAVOH barrier layer and thereby allowed the amount of HSG in the container to increase between day 29 and day 275. The container formed from the multi-layer construction of Example 4 did not initially reduce the amount of HSG sealed in the container by day 131, but thereafter did reduce the amount of HSG from day 131 up until at least day 255.

Further analysis was conducted on the following Examples 5-14 involving structures including comparative odd numbered Examples 5, 7, 9, and 11 not including HAVOH, and respectively corresponding even numbered Examples 6, 8, 10, and 12-14 including HAVOH in accordance with the present subject matter. The following Table 7 indicates the construction of various barrier structures and oxygen transmission through the structures under two different conditions of temperature and relative humidity. Example 14 is the same as Example 1 above.

TABLE 7
Oxygen Permeability in Examples 5-14

| | | | Oxygen Transmission | |
|---|---|---|---|---|
| | | | @ 23° C. and | @ 37° C. and |
| | Construction | Caliper | 0% RH | 90% RH |
| Sample | Permeant side = Left | (μm) | (cc/m²-day) | (cc/m²-day) |
| 5 | BOPET (36 μm) | 36 | 39.43 | 51.66 |
| 6 | BOPET (36 μm)/HAVOH (1.20 gsm) | 37 | 2.54 | 52.74 |
| 7 | BOPET (25 μm) | 23 | 64.60 | 91.80 |
| 8 | BOPET (25 μm)/HAVOH (0.10 gsm) | 23 | 26.00 | 94.40 |
| 9 | BOPP (50 μm) | 49 | 786 | 1,660 |
| 10 | BOPP (50 μm)/HAVOH (0.04 gsm) | 50 | 326 | 1,840 |
| 11 | BOPET (36 μm)/PSA/BOPET (36 μm) | 86 | 19.92 | 26.50 |
| 12 | BOPET (36 μm)/HAVOH (2.20 gsm)/BOPET (36 μm) | 69 | 2.27 | 25.84 |
| 13 | BOPET (36 μm)/HAVOH (1.20 gsm)/PSA/BOPET (36 μm) | 94 | 5.45 | 26.28 |
| 14 | BOPET (36 μm)/HAVOH (1.20 gsm)/PSA/LLDPE | 114 | 6.74 | 54.04 |

As can be seen, under conditions of 0% relative humidity (RH), the barrier constructions including HAVOH (Examples 6, 8, 10, 12-14) reduced the amount of oxygen transmitted through the barrier constructions compared to comparable constructions without HAVOH (Examples 5, 7, 9, 11). However, under conditions of 90% RH, the barrier constructions including HAVOH (Examples 6, 8, 10, 12-14) failed to reduce the amount of oxygen transmitted through the barrier constructions, and in fact allow a greater amount of oxygen transmission, compared to comparable constructions without HAVOH (Examples 5, 7, 9, 11). This analysis indicates that HAVOH loses it barrier properties when in highly humid environments and will need to have adequate MVTR protection to properly function as a barrier in these highly humid environments.

Many other benefits will no doubt become apparent from future application and development of this technology.

All patents, applications, standards, and articles noted herein are hereby incorporated by reference in their entirety.

The present subject matter includes all operable combinations of features and aspects described herein. Thus, for example if one feature is described in association with an embodiment and another feature is described in association with another embodiment, it will be understood that the present subject matter includes embodiments having a combination of these features.

As described hereinabove, the present subject matter solves many problems associated with previous strategies, systems and/or devices. However, it will be appreciated that various changes in the details, materials and arrangements of components, which have been herein described and illustrated in order to explain the nature of the present subject matter, may be made by those skilled in the art without departing from the principle and scopes of the claimed subject matter, as expressed in the appended claims.

What is claimed is:

1. A method of forming a layer of highly amorphous vinyl alcohol polymer on a substrate, the method comprising:
dissolving highly amorphous vinyl alcohol polymer in solvent to form a solution;
applying the solution to the substrate;
substantially removing solvent from the solution to produce a layer of highly amorphous vinyl alcohol polymer on the substrate.

2. The method of claim 1, wherein the highly amorphous vinyl alcohol polymer comprises a resin composition including a polyvinyl alcohol (PVA) resin having a 1,2-diol structure of formula (1): 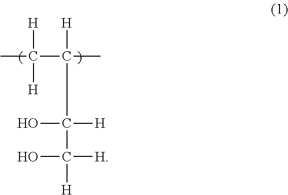
and an alkylene oxide adduct of a polyvalent alcohol containing 5 to 9 moles of an alkylene oxide per 1 mole of the polyvalent alcohol.

3. The method of claim 2, wherein the PVA resin has a saponification degree of 80 mol % to 97.9 mol %.

4. The method of claim 1, wherein the solvent includes water.

5. The method of claim 4, wherein the solution further includes at least one of glycerin and ethanol.

6. The method of claim 1, wherein the solution comprises about 0.1-90 wt % highly amorphous vinyl alcohol polymer.

7. The method of claim 1, wherein the solution comprises about 0.1-35 wt % highly amorphous vinyl alcohol polymer.

8. The method of claim 1, wherein the applying step includes at least one of gravure coating, reverse gravure coating, offset gravure coating, curtain coating, roll coating, brush coating, knife-over roll coating, metering rod coating, reverse roll coating, doctor knife coating, dip coating, die coating, spray coating, printing, electrostatic coating, flow coating, and spin coating.

9. The method of claim 1, wherein the solution is applied to the substrate as a substantially continuous layer.

10. The method of claim 1, wherein the solution is applied at a wet coating weight of about 0.1-100 g/m².

11. The method of claim 1, wherein substantially removing solvent from the solution results in the highly amorphous vinyl alcohol polymer being under conditions of less than about 65% relative humidity.

12. The method of claim 1, wherein the layer of highly amorphous vinyl alcohol polymer has a dry coating weight of about 0.1-85 g/m².

13. The method of claim 1, wherein the layer of highly amorphous vinyl alcohol polymer is a substantially continuous layer.

14. The method of claim 1, wherein the substrate is a water-impermeable film.

15. The method of claim 1, wherein the substrate comprises polyethylene terephthalate film.

16. A layer of highly amorphous vinyl alcohol polymer made by the methods of claim 1.

17. A method of improving gas barrier properties of a film, the method comprising:
providing a solution of highly amorphous vinyl alcohol polymer dissolved in a solvent;
applying the solution on a film to thereby form a coating layer on the film;
evaporating the solvent from the coating layer to form a barrier coating of dried highly amorphous vinyl alcohol polymer on the film, the barrier coating having a coating weight of about 0.01-85 g/m².

18. The method of claim 17, wherein the highly amorphous vinyl alcohol polymer comprises a resin composition including a polyvinyl alcohol (PVA) resin having a 1,2-diol structure of formula (1): 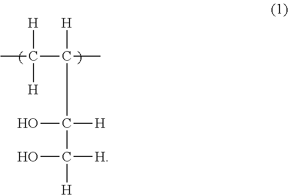
and an alkylene oxide adduct of a polyvalent alcohol containing 5 to 9 moles of an alkylene oxide per 1 mole of the polyvalent alcohol.

19. The method of claim 17, wherein the PVA resin has a saponification degree of 80 mol % to 97.9 mol %.

20. The method of claim 17, wherein the solvent includes water.

21. The method of claim 17, wherein the solution further includes at least one of glycerin and ethanol.

22. The method of claim 17, wherein the solution comprises about 0.1-90 wt % highly amorphous vinyl alcohol polymer.

23. The method of claim 17, wherein the solution comprises about 0.1-35 wt % highly amorphous vinyl alcohol polymer.

24. The method of claim 17, wherein applying includes at least one of gravure coating, reverse gravure coating, offset gravure coating, curtain coating, roll coating, brush coating, knife-over roll coating, metering rod coating, reverse roll coating, doctor knife coating, dip coating, die coating, spray coating, printing, electrostatic coating, flow coating, and spin coating.

25. The method of claim 17, wherein applying includes at least one of reverse gravure coating and curtain coating.

26. The method of claim 17, wherein the solution is applied to the film as a substantially continuous layer.

27. The method of claim 17, wherein the solution is applied at a wet coating weight of about 0.1-100 g/m².

28. The method of claim 17, wherein evaporating the solvent from the coating layer results in the barrier coating being in a dry state.

29. The method of claim 17, wherein the barrier coating has a dry coating weight of about 0.1-85 g/m².

30. The method of claim 17, wherein the barrier coating is a substantially continuous layer.

31. The method of claim 17, further comprising restricting liquid water and water-vapor from reaching the barrier coating such that the barrier coating remains dry and is not subjected to conditions of more than 65% relative humidity.

32. The method of claim 17, wherein the film is moisture-impermeable.

33. The method of claim 17, wherein the film comprises polyethylene terephthalate.

34. The method of claim 17, further comprising depositing a layer of adhesive to the barrier coating on a side of the barrier coating opposite from the film.

35. The method of claim 34, wherein the adhesive is a pressure sensitive adhesive.

36. The method of claim 34, wherein the adhesive is applied at a coating weight of about 4-30 g/m².

37. The method of claim 17, wherein a tie layer is positioned between the coating layer and the film.

38. The method of claim 17, wherein the film is a first film and the method further comprises positioning a second film on a side of the barrier coating opposite from the first film, the second film being moisture-impermeable.

39. The method of claim 38, wherein the second film comprises at least one of linear low density polyethylene (LLDPE), metallocene linear low density polyethylene (mLLDPE), and ultra-low density polyethylene (ULDPE), high density polyethylene (HDPE), polypropylene, ionomers, and polybutylene.

40. A barrier coating formed by the methods of claim 17.

41. A method of making a gas barrier construction configured to limit the amount of gas transmitted through a gas barrier construction from a second side of the gas barrier construction to a first side of the gas barrier construction, the method comprising:
providing a first moisture impermeable film layer having a first face and an oppositely directed second face;
applying a solution comprising highly amorphous vinyl alcohol polymer dissolved in a solvent to the first face of the first moisture impermeable film to thereby form a coating layer;
drying the coating layer by substantially removing the solvent from the coating layer to thereby form a barrier layer;
disposing an adhesive layer on a side of the barrier layer opposite from the first moisture impermeable film layer;
positioning a second moisture impermeable film layer on a side of the adhesive layer opposite from the barrier layer thereby forming the gas barrier construction,
wherein the second face of the first moisture impermeable film layer is directed toward the second side of the gas barrier construction, and
wherein the second moisture impermeable film layer includes a face that is oppositely directed from the adhesive layer and is directed toward the first side of the gas barrier construction.

42. The method of claim 41, wherein the highly amorphous vinyl alcohol polymer comprises a resin composition including a polyvinyl alcohol (PVA) resin having a 1,2-diol structure of formula (1): 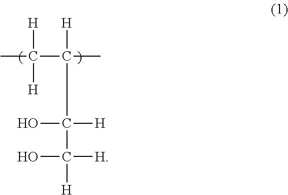
and an alkylene oxide adduct of a polyvalent alcohol containing 5 to 9 moles of an alkylene oxide per 1 mole of the polyvalent alcohol.

43. The method claim of claim 41, wherein the PVA resin has a saponification degree of 80 mol % to 97.9 mol %.

44. The method of claim 41, wherein the solution comprises water and optionally at least one of glycerin and ethanol.

45. The method of claim 41, wherein the solution comprises about 0.1-90 wt % highly amorphous vinyl alcohol polymer.

46. The method of claim 41, wherein the solution comprises about 0.1-35 wt % highly amorphous vinyl alcohol polymer.

47. The method of claim 41, wherein the applying step includes at least one of gravure coating, reverse gravure coating, offset gravure coating, curtain coating, roll coating, brush coating, knife-over roll coating, metering rod coating, reverse roll coating, doctor knife coating, dip coating, die coating, spray coating, printing, electrostatic coating, flow coating, and spin coating.

48. The method of claim 41, wherein the barrier layer is substantially continuous and has a dry coating weight of about 0.1-85 g/m².

49. The method of claim 41, wherein the second face of the first moisture impermeable film layer defines the second side of the gas barrier construction.

50. The method of claim 41, wherein the face of the second moisture impermeable film layer that is oppositely directed from the adhesive layer defines the first side of the gas barrier construction.

51. The method of claim 41, wherein the adhesive layer is directly abutting the barrier layer.

52. The method of claim 41, wherein the barrier layer is not subjected to conditions of more than 65% relative humidity.

53. The method of claim 41, further comprising incorporating the barrier construction into a container.

54. The method of claim 41, further comprising sealing the barrier construction to itself to form a container.

55. A gas barrier construction made by the methods of claim 41.
